(19) United States
(12) Patent Application Publication
(10) Pub. No.: US 2025/0151507 A1
(43) Pub. Date: May 8, 2025

(54) DISPLAY PANEL, METHOD OF MANUFACTURING THE DISPLAY PANEL, AND DISPLAY APPARATUS

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Youqin ZHU, Beijing (CN); Dong LI, Beijing (CN); Yichi ZHANG, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/261,241

(22) PCT Filed: Jun. 30, 2022
(86) PCT No.: PCT/CN2022/103026

§ 371 Date: Dec. 5, 2024

(51) Int. Cl. H10K 50/16; H10K 50/115; H10K 59/12; H10K 59/35; H10K 102/00

(52) U.S. Cl. CPC H10K 50/166; H10K 50/115; H10K 59/1201; H10K 59/35; H10K 2102/351

(57) ABSTRACT

A display panel includes a plurality of light-emitting devices. Any light-emitting device includes a first electrode, a second electrode, a quantum dot light-emitting layer, and at least two electron transporting layers. The quantum dot light-emitting layer is located between the first electrode and the second electrode. The at least two electron transporting layers are stacked and located between the second electrode and the quantum dot light-emitting layer. The plurality of light-emitting devices include a first light-emitting device used to emit light of a first color, and a second light-emitting device used to emit light of a second color; and a wavelength of the light of the first color is greater than a wavelength of the light of the second color. A number of electron transporting layers in the first light-emitting device is less than a number of electron transporting layers in the second light-emitting device.

### CROSS-REFERENCE TO RELATED APPLICATION

The present application is a national phase entry under 35 USC 371 of International Patent Application No. PCT/CN2022/103026, filed on Jun. 30, 2022, which is incorporated herein by reference in its entirety.

### TECHNICAL FIELD

The present disclosure relates to the field of display technologies, and in particular, to a display panel, a method of manufacturing the display panel and a display apparatus.

### BACKGROUND

The display panel generally includes a plurality of light-emitting devices for emitting light outwardly, so that the display panel can perform an image display function.

### SUMMARY

In an aspect, a display panel is provided. The display panel includes a plurality of light-emitting devices. Any of the light-emitting devices includes a first electrode, a second electrode, a quantum dot light-emitting layer, and at least two electron transporting layers. The quantum dot light-emitting layer is located between the first electrode and the second electrode. The at least two electron transporting layers are stacked and located between the second electrode and the quantum dot light-emitting layer. The first light-emitting device is used to emit light of a first color, the second light-emitting device is used to emit light of a second color, and a wavelength of the light of the first color is greater than a wavelength of the light of the second color. A number of electron transporting layers in the first light-emitting device is less than a number of electron transporting layers in the second light-emitting device.

In some embodiments, a sum of thicknesses of at least two electron transporting layers in the first light-emitting device is greater than a sum of thicknesses of at least two electron transporting layers in the second light-emitting device.

In some embodiments, the display panel further includes a driving backplate, the plurality of light-emitting devices are located at a side of the driving backplate. The second electrode is close to the driving backplate relative to the first electrode. The first light-emitting device includes a first first electrode, and the second light-emitting device includes a second first electrode. A distance between a surface of the first first electrode away from the driving backplate and the driving backplate is greater than a distance between a surface of the second first electrode away from the driving backplate and the driving backplate.

In some embodiments, at least two electron transporting layers in the first light-emitting device include a first electron transporting layer and a second electron transporting layer, an electron mobility of the second electron transporting layer is less than an electron mobility of the first electron transporting layer.

In some examples, the first electron transporting layer is close to the second electrode relative to the second electron transporting layer. An energy of a conduction band minimum of the first electron transmission layer is less than an energy of a conduction band minimum of the second electron transmission layer.

In some embodiments, a material of the first electron transporting layer includes any one of zinc oxide (ZnO), gallium zinc oxide (GZO), aluminum zinc oxide (AZO), indium zinc oxide (IZO), indium gallium zinc oxide (IGZO), and magnesium zinc oxide (ZnMgO), a material of the second electron transporting layer includes any one of ZnO, GZO, AZO, IZO, IGZO, and ZnMgO, and the material of the first electron transporting layer is different from the material of the second electron transporting layer.

In some embodiments, the material of the second electron transporting layer includes ZnMgO; in the second electron transporting layer, a molar percentage of magnesium (Mg) is greater than 0 and less than or equal to 50%, and a sum of the molar percentage of Mg and a molar percentage of zinc (Zn) is 1.

In some embodiments, in the second electron transporting layer, the molar percentage of Mg is in a range of 1% to 20%, inclusive.

In some embodiments, in the second electron transporting layer, the molar percentage of Mg is approximately 5%.

In some embodiments, a thickness of the first electron transporting layer is greater than 0 nm and less than or equal to 60 nm; and/or a thickness of the second electron transporting layer is greater than 0 nm and less than or equal to 60 nm. The thickness of the first electron transporting layer is greater than the thickness of the second electron transporting layer.

In some embodiments, the thickness of the first electron transporting layer is in a range of 30 nm to 50 nm, inclusive; and/or, the thickness of the second electron transporting layer is in a range of 1 nm to 30 nm, inclusive.

In some embodiments, the thickness of the first electron transporting layer is approximately 45 nm; and/or the thickness of the second electron transporting layer is approximately 15 nm.

In some embodiments, the plurality of light-emitting devices further include a third light-emitting device. The third light-emitting device is used to emit light of a third color, and the wavelength of the light of the second color is greater than a wavelength of the light of the third color. The number of the electron transporting layers in the first light-emitting device is less than a number of electron transporting layers in the third light-emitting device.

In some embodiments, at least two electron transporting layers of at least one light-emitting device of the second light-emitting device and the third light-emitting device include a third electron transporting layer, a fourth electron transporting layer, and a fifth electron transporting layer. An electron mobility of the fourth electron transporting layer is smaller than an electron mobility of the third electron transporting layer, and the electron mobility of the fourth electron transporting layer is smaller than an electron mobility of the fifth electron transporting layer.

In some embodiments, the third electron transporting layer, the fourth electron transporting layer, and the fifth electron transporting layer are sequentially far away from the second electrode in a direction from the second electrode to the quantum dot light-emitting layer. An energy of a conduction band minimum of the third electron transporting layer is less than an energy of a conduction band minimum of the fourth electron transporting layer, or the energy of the conduction band minimum of the fourth electron transporting layer is less than an energy of a conduction band minimum of the fifth electron transporting layer.

In some embodiments, the energy of the conduction band minimum of the third electron transporting layer is equal to the energy of the conduction band minimum of the fifth electron transporting layer.

In some embodiments, a material of the third electron transporting layer includes any one of ZnO, GZO, AZO, IZO, IGZO and ZnMgO. A material of the fourth electron transporting layer includes any one of ZnO, GZO, AZO, IZO, IGZO, and ZnMgO. A material of the fifth electron transporting layer includes any one of ZnO, GZO, AZO, IZO, IGZO, and ZnMgO. The material of the fourth electron transporting layer is different from the material of the third electron transporting layer, and/or the material of the fourth electron transporting layer is different from the material of the fifth electron transporting layer.

In some embodiments, the material of the fourth electron transporting layer includes ZnMgO. In the fourth electron transporting layer, a molar percentage of Mg is greater than 0 and less than or equal to 50%, and a sum of the molar percentage of Mg and a molar percentage of Zn is 1.

In some embodiments, in the fourth electron transporting layer, the molar percentage of Mg is in a range of 1% to 20%, inclusive.

In some embodiments, in a case where the second light-emitting device includes a third electron transporting layer, a fourth electron transporting layer, and a fifth electron transporting layer, in the fourth electron transporting layer, the molar percentage of Mg is approximately 8%.

In some embodiments, in a case where the second light-emitting device includes a third electron transporting layer, a fourth electron transporting layer, and a fifth electron transporting layer, a thickness of the third electron transporting layer is greater than 0 nm and less than or equal to 40 nm, a thickness of the fourth electron transporting layer is greater than 0 nm and less than or equal to 30 nm, a thickness of the fifth electron transporting layer is greater than 0 nm and less than or equal to 40 nm. In a case where the third light-emitting device includes a third electron transporting layer, a fourth electron transporting layer, and a fifth electron transporting layer, a thickness of the third electron transporting layer is greater than 0 nm and less than or equal to 30 nm, a thickness of the fourth electron transmission layer is greater than 0 nm and less than or equal to 20 nm, and a thickness of the fifth electron transporting layer is greater than 0 nm and less than or equal to 30 nm.

In some embodiments, in the case where the second light-emitting device includes the third electron transporting layer, the fourth electron transporting layer, and the fifth electron transporting layer; wherein the thickness of the third electron transporting layer is in a range of 5 nm to 20 nm, inclusive, the thickness of the fourth electron transporting layer is in a range of 1 nm to 15 nm, inclusive, and the thickness of the fifth electron transporting layer is in a range of 5 nm to 20 nm, inclusive. In the case where the third light-emitting device includes the third electron transporting layer, the fourth electron transporting layer, and the fifth electron transporting layer; wherein the thickness of the third electron transporting layer is in a range of 5 nm to 15 nm, inclusive, the thickness of the fourth electron transporting layer is in a range of 1 nm to 15 nm, inclusive, and the thickness of the fifth electron transporting layer is in a range of 5 nm to 15 nm, inclusive.

In some embodiments, in the case where the second light-emitting device includes the third electron transporting layer, the fourth electron transporting layer, and the fifth electron transporting layer; the thickness of the third electron transporting layer is approximately 10.5 nm, the thickness of the fourth electron transporting layer is approximately 9 nm, and the thickness of the fifth electron transporting layer is approximately 10.5 nm.

In some embodiments, the light of the first color is red light, the light of the second color is green light, and the light of the third color is blue light.

In some embodiments, a sum of thicknesses of the at least two electron transporting layers is in a range of 5 nm to 150 nm, inclusive.

In some embodiments, the sum of the thicknesses of the at least two electron transporting layers is in a range of 20 nm to 70 nm, inclusive.

In some embodiments, the sum of the thicknesses of the at least two electron transporting layers is in a range of 20 nm to 60 nm, inclusive.

In some embodiments, any of the light-emitting devices further includes an electron injection layer, a hole injection layer, a hole transporting layer, and a light coupling layer. The electron injection layer is located between the second electrode and the at least two electron transporting layers. The hole injection layer is located between the first electrode and the quantum dot light-emitting layer. The hole transporting layer is located between the hole injection layer and the quantum dot light-emitting layer. The light coupling layer is located on a side of the first electrode away from the hole injection layer.

In another aspect, a method of manufacturing a display panel is provided. The method of manufacturing the display panel includes forming a plurality of light-emitting devices. A step of forming a light-emitting device includes: forming a second electrode; forming at least two electron transporting layers on a side of the second electrode by magnetron sputtering, a material of at least one electron transporting layer of the at least two electron transporting layers including an oxide; forming a quantum dot light-emitting layer on a side of the at least two electron transporting layers away from the second electrode; and forming a first electrode on a side of the quantum dot light-emitting layer away from the at least two electron transporting layers.

In yet another aspect, a display apparatus is provided. The display apparatus includes the display panel as described in the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings. In addition, the accompanying drawings in the following description may be regarded as schematic diagrams, and are not limitations on actual sizes of products, actual processes of methods and actual timings of signals involved in the embodiments of the present disclosure.

FIG. 1 is a diagram showing a structure of a display apparatus, in accordance with some embodiments;

FIG. 2A is a diagram showing a structure of a display panel, in accordance with some embodiments;

FIG. 2B is a diagram showing a structure of another display panel, in accordance with some embodiments;

FIG. 3A is a diagram showing a structure of yet another display panel, in accordance with some embodiments;

FIG. 3B is a diagram showing a structure of yet another display panel, in accordance with some embodiments;

FIG. 3C is a diagram showing a structure of yet another display panel, in accordance with some embodiments;

FIG. 3D is a diagram showing a structure of yet another display panel, in accordance with some embodiments;

FIG. 4 is a curve graph showing a variation of luminance of a light-emitting device with a sum of thicknesses of electron transporting layers, in accordance with some embodiments;

FIG. 5A is a diagram showing a structure of yet another display panel, in accordance with some embodiments;

FIG. 5B is a diagram showing a structure of yet another display panel, in accordance with some embodiments;

FIG. 6 is a diagram showing a structure of a light-emitting device, in accordance with some embodiments;

FIG. 7A is a diagram showing an energy level relationship of a first electron transporting layer and a second electron transporting layer, in accordance with some embodiments;

FIG. 7B is a diagram showing an energy level relationship of a first electron transporting layer and a second electron transporting layer, in accordance with some other embodiments;

FIG. 7C is a diagram showing an energy level relationship of a first electron transporting layer and a second electron transporting layer, in accordance with yet some other embodiments;

FIG. 7D is a diagram showing an energy level relationship of a first electron transporting layer and a second electron transporting layer, in accordance with yet some other embodiments;

FIG. 8 is a diagram showing an energy level structure of a light-emitting device, in accordance with some embodiments;

FIG. 9A is a curve graph showing a variation of a current density with a voltage, in accordance with some embodiments;

FIG. 9B is a curve graph showing a variation of luminance with a voltage, in accordance with some embodiments;

FIG. 9C is a curve graph showing a variation of an external quantum efficiency with a voltage, in accordance with some embodiments;

FIG. 10A is a curve graph showing a variation of a current density with a voltage, in accordance with some other embodiments;

FIG. 10B is a curve graph showing a variation of luminance with a voltage, in accordance with some other embodiments;

FIG. 10C is a curve graph showing a variation of an external quantum efficiency with a voltage, in accordance with some other embodiments;

FIG. 11 is a diagram showing structures of a first light-emitting device and a second light-emitting device, in accordance with some embodiments;

FIG. 12A is a diagram showing an energy level relationship of a third electron transporting layer, a fourth electron transporting layer and a fifth electron transporting layer, in accordance with some embodiments;

FIG. 12B is a diagram showing an energy level relationship of a third electron transporting layer, a fourth electron transporting layer and a fifth electron transporting layer, in accordance with some other embodiments;

FIG. 12C is a diagram showing an energy level relationship of a sixth electron transporting layer, a seventh electron transporting layer, an eighth electron transporting layer and a ninth electron transporting layer, in accordance with some embodiments;

FIG. 12D is a diagram showing an energy level relationship of a sixth electron transporting layer, a seventh electron transporting layer, an eighth electron transporting layer, a ninth electron transporting layer and a tenth electron transporting layer, in accordance with some embodiments;

FIG. 13 is a diagram showing an energy level structure of a light-emitting device, in accordance with some other embodiments;

FIG. 14A is a curve graph showing a variation of a current density with a voltage, in accordance with yet some other embodiments;

FIG. 14B is a curve graph showing a variation of luminance with a voltage, in accordance with yet some other embodiments;

FIG. 14C is a curve graph showing a variation of an external quantum efficiency with a voltage, in accordance with yet some other embodiments;

FIG. 15A is curve graph showing a variation of a current density with a voltage, in accordance with yet some other embodiments;

FIG. 15B is a curve graph showing a variation of luminance with a voltage, in accordance with yet some other embodiments;

FIG. 15C is a curve graph showing a variation of an external quantum efficiency with a voltage, in accordance with yet some other embodiments; and

FIG. 16 is a flow diagram of a method of manufacturing a light-emitting device, in accordance with some embodiments.

### DETAILED DESCRIPTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term such as “about”, “substantially” or “approximately” includes a stated value and an average value within an acceptable range of deviation of a particular value. The acceptable range of deviation is determined by a person of ordinary skill in the art in view of measurement in question and errors associated with measurement of a particular quantity (i.e., limitations of a measurement system).

As used herein, the term such as “parallel”, “perpendicular” or “equal” includes a stated condition and a condition similar to the stated condition, a range of the similar condition is within an acceptable range of deviation, and the acceptable range of deviation is determined by a person of ordinary skill in the art in view of measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; the term “equal” includes absolute equality and approximate equality, and an acceptable range of deviation of the approximate equality may be that, for example, a difference between the two that are equal is less than or equal to 5% of either of the two.

It will be understood that, in a case where a layer or an element is referred to as being on another layer or a substrate, it may be that the layer or the element is directly on the another layer or the substrate, or there may be a middle layer between the layer or the element and the another layer or the substrate.

Exemplary embodiments are described herein with reference to sectional views and/or plan views as idealized exemplary drawings. In the accompanying drawings, thicknesses of layers and sizes of regions are enlarged for clarity. Thus, variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

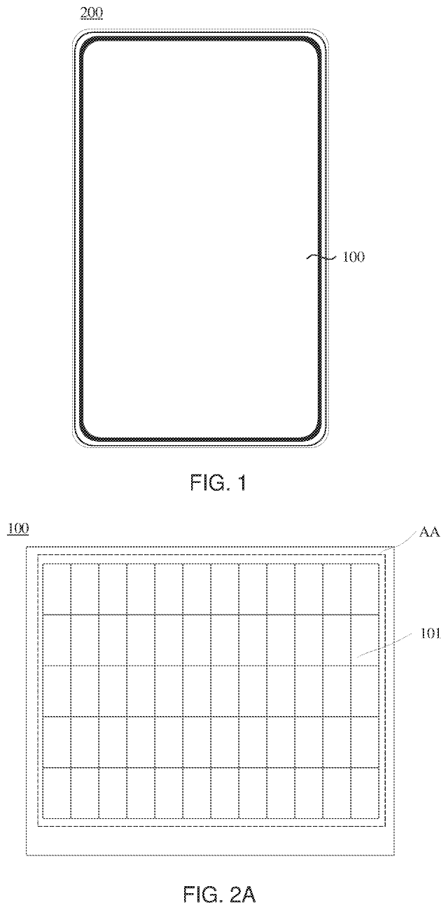

FIG. 1 is a diagram showing a structure of a display apparatus, in accordance with some embodiments.

As shown in FIG. 1, some embodiments of the present disclosure provide a display apparatus 200. In some examples, the display apparatus 200 may be a laptop, a mobile phone, a wireless apparatus, a personal digital assistant (PDA), a hand-held or portable computer, a global positioning system (GPS) receiver/navigator, a camera, a moving picture experts group 4 (MP4) video player, a video camera, a game console, a watch, a clock, a calculator, a television monitor, a flat panel display, a computer monitor, an automobile display (e.g., an odometer display), a navigator, a cockpit controller and/or display, a camera view display (e.g., a display of a rear-view camera in a vehicle), an electronic photo, an electronic billboard or sign, a projector, a packaging and aesthetic structure (e.g., a display for displaying an image of a piece of jewelry), etc.

As shown in FIG. 1, the display apparatus 200 includes a display panel 100. It will be understood that the display panel 100 is used to display image information. For example, the display panel 100 may be used to display a still image, such as a picture or photograph. Alternatively, the display panel 100 may be used to display dynamic images such as video or game pictures.

The display apparatus 200 is not further limited in the embodiments of the present disclosure, and the display panel 100 will be exemplarily described below.

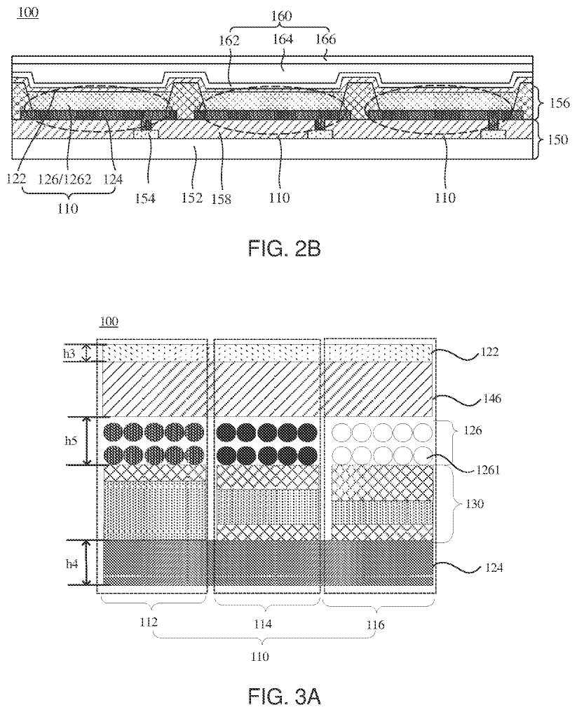

FIG. 2A is a diagram showing a structure of a display panel, in accordance with some embodiments.

In some examples, as shown in FIG. 2A, the display panel 100 includes a plurality of sub-pixels 101, and the plurality of sub-pixels 101 are located in a display area AA of the display panel 100 and arranged in an array.

It will be understood that the sub-pixel 101 is the smallest unit of the display panel 100 for performing an image display. Each sub-pixel Q may emit light of a single color such as red, green or blue. The display panel 100 may include a plurality of red sub-pixels, a plurality of green sub-pixels and a plurality of blue sub-pixels. Red light, green light and blue light with different intensities may be obtained by adjusting the luminance (gray scale) of the sub-pixels 101 of different colors; moreover, at least two of the red light, the green light and the blue light with different intensities are superposed, so that the light of more colors may be displayed, and full-color display of the display panel 100 is achieved.

FIG. 2B is a diagram showing a structure of another display panel, in accordance with some embodiments.

As shown in FIG. 2B, in some examples, the display panel 100 includes a plurality of light-emitting devices 110. It will be understood that a light-emitting device 110 is disposed in a sub-pixel 101, so that the display panel 100 may realize an image display function.

In some examples, the plurality of light-emitting devices 110 are used to emit light of different colors. For example, some (two or more) of the plurality of light-emitting devices 110 are used to emit red light, some other (two or more) of the plurality of light-emitting devices 110 are used to emit blue light, and yet some other (two or more) of the plurality of light-emitting devices 110 are used to emit green light, so that the display panel 100 may realize the full-color display.

In some examples, as shown in FIG. 2B, the display panel 100 further includes a driving backplate 150. The plurality of light-emitting devices 110 are located on a side of the driving backplate 150.

It will be understood that the plurality of light-emitting devices 110 are electrically connected to the driving backplate 150, and the driving backplate 150 is used to drive the plurality of light-emitting devices 110 to emit light independently, thereby improving the display performance of the display panel 100.

For example, as shown in FIG. 2B, the driving backplate 150 includes a substrate 152 and a driving circuit layer 158.

For example, the substrate 152 may be a rigid substrate. For another example, the substrate 152 may be a flexible substrate. For example, a material of the substrate 152 includes any one of plastic, FR-4 grade material, resin, glass, quartz, polyimide, or polymethylmethacrylate (PMMA).

In some examples, as shown in FIG. 2B, the driving circuit layer 158 is disposed on a side of the substrate 152. The driving circuit layer 158 is provided with a plurality of pixel driving circuits 154 therein, and a pixel driving circuit 154 is electrically connected to a light-emitting device 110, so that the driving backplate 150 may drive the plurality of light-emitting devices 110 separately, and thus the plurality of light-emitting devices 110 may emit light independently.

In some examples, the pixel driving circuit 154 includes thin film transistors (TFTs) and a capacitor, and the TFTs are electrically connected to the capacitor. For example, the pixel driving circuit 154 may be a 2T1C pixel driving circuit (i.e., including 2 TFTs and 1 capacitor), a 7T1C pixel driving circuit (i.e., including 7 TFTs and 1 capacitor), or a 3T1C pixel driving circuit (i.e., including 3 TFTs and 1 capacitor) or the like.

In some examples, as shown in FIG. 2B, any light-emitting device 110 includes a first electrode 122, a second electrode 124, and a quantum dot light-emitting layer 126. The quantum dot light-emitting layer 126 is located between the first electrode 122 and the second electrode 124.

In some examples, the light-emitting device 110 is a quantum dot light-emitting diode (QLED). It will be understood that, the QLED has advantages of narrow light emission spectrum, high color purity, high luminous efficiency, and the like.

In some examples, the first electrode 122 is an anode, and the second electrode 124 is a cathode. In some other examples, the first electrode 122 is a cathode, and the second electrode 124 is an anode. The embodiments of the present disclosure will be described by taking an example in which the first electrode 122 is an anode and the second electrode 124 is a cathode.

For example, as shown in FIG. 2B, the second electrode 124 is disposed on a side of the driving circuit layer 158 away from the substrate 152, and is electrically connected to the pixel driving circuit 154. In some examples, the second electrode 124 may be electrically connected to a driving transistor of the pixel driving circuit 154.

In some examples, as shown in FIG. 2B, the display panel 100 further includes a pixel definition layer 156. The pixel definition layer 156 is disposed on a side of the second electrode 124 away from the driving circuit layer 158. The first pixel definition layer 156 has a plurality of openings. The quantum dot light-emitting layer 126 includes a plurality of effective light-emitting portions 1262, and an effective light-emitting portion 1262 is located in an opening.

For example, as shown in FIG. 2B, the first electrode 122 is located on a side of the quantum dot light-emitting layer 126 away from the second electrode 124.

It will be understood that the first electrode 122 is used to provide holes, and the second electrode 124 is used to provide electrons. The holes provided by the first electrode 122 and the electrons provided by the second electrode 124 may move to the quantum dot light-emitting layer 126, and recombine in the quantum dot light-emitting layer 126 to emit light, so that the light-emitting device 110 may emit light.

In some examples, a structure of which the second electrode 124 is close to the driving backplate 150 relative to the first electrode 122 may be referred to as an inverted structure, and a structure of which the second electrode 124 is far away from the driving backplate 150 relative to the first electrode 122 may be referred to as an upright structure. The embodiments of the present disclosure are illustrated by taking the inverted structure (i.e., the second electrode 124 is close to the driving backplate 150 relative to the first electrode 122) as an example.

It can be seen from the above, the quantum dot light-emitting layer 126 is used to emit light. In some examples, the first electrode 122 is made of a transparent material, so that light emitted from the quantum dot light-emitting layer 126 may be emitted through the first electrode 122. In this case, the light-emitting device 110 is of a top emission structure.

In some other examples, the second electrode 124 is made of a transparent material, so that light emitted from the quantum dot light-emitting layer 126 may be emitted through the second electrode 124. In this case, the light-emitting device 110 is of a bottom emission structure.

In yet some other examples, the first electrode 122 and the second electrode 124 are both made of transparent materials, so that light emitted from the quantum dot light-emitting layer 126 may be emitted through the first electrode 122 and the second electrode 124. In this case, the light-emitting device 110 is a of double-sided emission structure. The embodiments of the present disclosure are illustrated by taking an example in which the light-emitting device 110 is of a top emission structure.

In some other examples, as shown in FIG. 2B, the display panel 100 further includes an encapsulation layer 160. The encapsulation layer 160 is located on a side of the light-emitting devices 110 away from the driving backplate 150 to protect the light-emitting devices 110.

For example, as shown in FIG. 2B, the encapsulation layer 160 includes a first encapsulation layer 162, a second encapsulation layer 164, and a third encapsulation layer 166. The first encapsulation layer 162, the second encapsulation layer 164 and the third encapsulation layer 166 are stacked and sequentially away from the light-emitting devices 110.

In some examples, the first encapsulation layer 162 and the third encapsulation layer 166 are both inorganic film layers, and the second encapsulation layer 164 is an organic film layer.

It will be understood that the encapsulation layer 160 may block external impurities, moisture, oxygen, or the like, thereby prolonging the service life of the light-emitting devices 110.

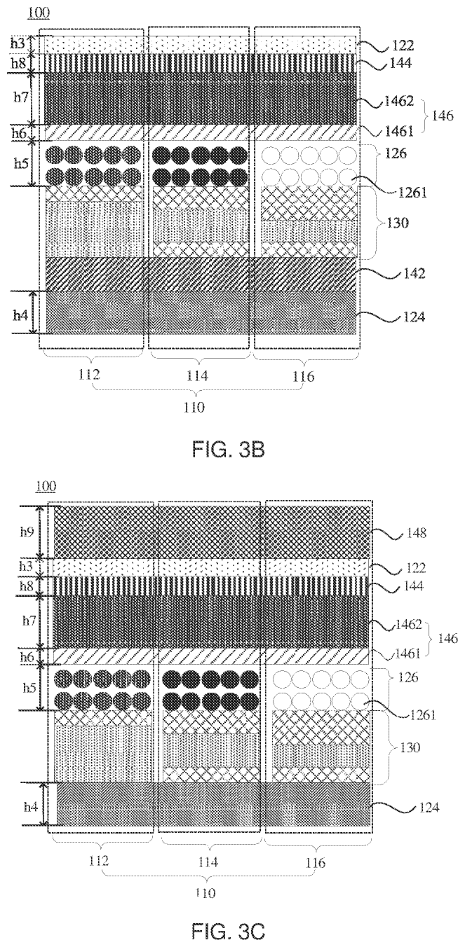

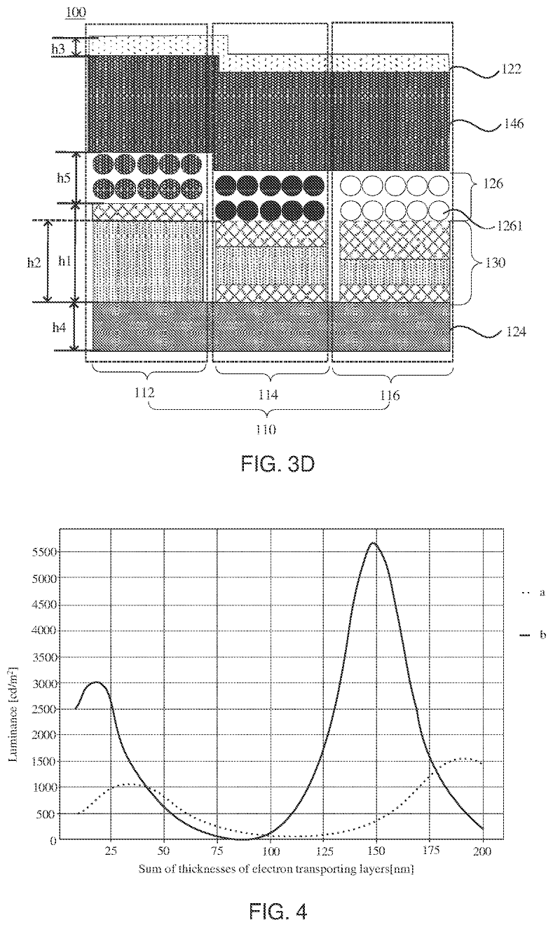

FIG. 3A is a diagram showing a structure of yet another display panel, in accordance with some embodiments. FIG. 3B is a diagram showing a structure of yet another display panel, in accordance with some embodiments. FIG. 3C is a diagram showing a structure of yet another display panel, in accordance with some embodiments.

In some examples, as shown in FIG. 3A, the quantum dot light-emitting layer 126 includes quantum dots (QDs) 1261. For example, a shape of the quantum dot 1261 may be spherical, tetrahedral, cylindrical, or disk-shaped.

In some examples, the quantum dot 1261 may have a core-shell structure, that is, the quantum dot 1261 have a quantum dot core and a quantum dot shell surrounding the quantum dot core. A color of the light emitted from the quantum dot light-emitting layer 126 may be adjusted by adjusting a size of the quantum dot core, so that the light-emitting device 110 may emit light of different colors.

For example, the quantum dot 1261 has narrower energy band gap as the size of the quantum dot core increases, and is thus configured to emit light with longer wavelength; the quantum dot 1261 has wider energy band gap as the size of the quantum dot core decreases, and is thus configured to emit light with shorter wavelength.

In some examples, as shown in FIG. 3A, the plurality of light-emitting devices 110 include a first light-emitting device 112 and a second light-emitting device 114; the first light-emitting device 112 is used to emit light of a first color, and the second light-emitting device 114 is used to emit light of a second color. A wavelength of the light of the first color is greater than a wavelength of the light of the second color.

In some examples, the light of the first color is red light (a wavelength of which is approximately 600 nm to 700 nm, inclusive), and the light of the second color is green light (a wavelength of which is approximately 500 nm to 570 nm, inclusive).

In some examples, the size of the quantum dot core of the quantum dot 1261 in the first light-emitting device 112 is greater than the size of the quantum dot core of the quantum dot 1261 in the second light-emitting device 114.

By adjusting the size of the quantum dot core of the quantum dot 1261 in different light-emitting devices 110 (the first light-emitting device 112 and the second light-emitting device 114), the first light-emitting device 112 and the second light-emitting device 114 may emit light of different colors.

The structure of the light-emitting device 110 will be described below with reference to FIGS. 3A to 3C.

It can be seen from the above, as shown in FIGS. 3A to 3C, any light-emitting device 110 includes a first electrode 122, a second electrode 124 and a quantum dot light-emitting layer 126 located between the first electrode 122 and the second electrode 124.

In some examples, a material of the first electrode 122 includes magnesium (Mg) and silver (Ag). For example, a mass ratio of Mg to Ag is 2:8, so that the first electrode 122 may provide more holes. A material of the second electrode 124 includes indium tin oxide (ITO), so that the second electrode 124 may provide more electrons.

In some examples, as shown in FIG. 3A, a thickness h3 of the first electrode 122 is in a range of 8 nm to 12 nm, inclusive. For example, the thickness h3 of the first electrode 122 may be in a range of 9 nm to 11 nm, inclusive, or a range of 9.5 nm to 10.5 nm, inclusive. For example, the thickness h3 of the first electrode 122 may be 9 nm, 10 nm, 11 nm, or the like.

In some examples, as shown in FIG. 3A, a thickness h4 of the second electrode 124 is in a range of 50 nm to 100 nm, inclusive. For example, the thickness h4 of the second electrode 124 may be in a range of 60 nm to 90 nm, inclusive, or a range of 70 nm to 80 nm, inclusive. For example, the thickness h4 of the second electrode 124 may be 60 nm, 70 nm, 80 nm, 90 nm, or the like.

It will be understood that, the thickness h3 of the first electrode 122 is set to be in a range of 8 nm to 12 nm, inclusive, and the thickness h4 of the second electrode 124 is set to be in a range of 50 nm to 100 nm, inclusive, it is possible to prevent the thickness of the first electrode 122 or the second electrode 124 from being too small (for example, the thickness of the first electrode 122 is less than 8 nm or the thickness of the second electrode 124 is less than 50 nm), and moreover, it is possible to prevent the thickness of the first electrode 122 or the second electrode 124 from being too large (for example, the thickness of the first electrode 122 is greater than 12 nm or the thickness of the second electrode 124 is greater than 100 nm), so that the first electrode 122 can provide sufficient holes for the quantum dot light-emitting layer 126, and the second electrode 124 can provide sufficient electrons for the quantum dot light-emitting layer 126. As a result, the luminous efficiency of the light-emitting device 110 is improved.

In some examples, the quantum dot light-emitting layer 126 may be formed on a side of the second electrode 124 by means of spin coating with a quantum dot solution, knife coating with a quantum dot solution, or ink-jet printing with a quantum dot solution.

For example, the quantum dot solution may be at least one of a group II-VI semiconductor compound (e.g., cadmium selenide (CdSe), zinc tellurium selenium (ZnTeSe)), a group III-V semiconductor compound (e.g., indium phosphide (InP)), a group IV-VI semiconductor compound (e.g., lead sulfide (PbS)). In some examples, the quantum dot solution may be a perovskite quantum dot solution.

It will be understood that in a case where the quantum dot light-emitting layer 126 is formed by means of spin coating with the quantum dot solution, a thickness h5 of the quantum dot light-emitting layer 126 may be controlled by controlling a concentration of the quantum dot solution or a rotation speed of the spin coating.

In some examples, as shown in FIG. 3A, the thickness h5 of the quantum dot light-emitting layer 126 is in a range of 10 nm to 80 nm, inclusive. For example, the thickness h5 of the quantum dot light-emitting layer 126 may be in a range of 20 nm to 50 nm, inclusive, or a range of 25 nm to 40 nm, inclusive. For example, the thickness h5 of the quantum dot light-emitting layer 126 may be 20 nm, 30 nm, 40 nm, 60 nm, 75 nm, or the like.

The thickness h5 of the quantum dot light-emitting layer 126 is set to be in a range of 10 nm to 80 nm, inclusive, it is possible to prevent the thickness of the quantum dot light-emitting layer 126 from being too small (e.g., less than 10 nm) or too large (e.g., greater than 80 nm), so that the luminous efficiency of the light-emitting device 110 is improved.

In some examples, as shown in FIG. 3B, the display panel 100 further includes a hole injection layer (HIL) 144. The hole injection layer 144 is disposed between the first electrode 122 and the quantum dot light-emitting layer 126.

In some examples, a material of the hole injection layer 144 includes molybdenum trioxide (MoO₃).

In some examples, a thickness h8 of the hole injection layer 144 is in a range of 2 nm to 20 nm, inclusive. For example, the thickness h8 of the hole injection layer 144 may be in a range of 3 nm to 17 nm, inclusive, or a range of 5 nm to 10 nm, inclusive. For example, the thickness h8 of the hole injection layer 144 may be 5 nm, 8 nm, 10 nm, 12 nm, or the like.

It will be understood that the provision of the hole injection layer 144 may increase the number of holes in the quantum dot light-emitting layer 126, thereby increasing the luminous efficiency of the light-emitting device 110.

In addition, the thickness h8 of the hole injection layer 144 is set to be in a range of 2 nm to 20 nm, inclusive, it is possible to prevent the thickness h8 of the hole injection layer 144 from being too small (e.g., less than 2 nm) or the thickness h8 of the hole injection layer 144 from being too large (e.g., greater than 20 nm), so that the luminous efficiency of the light-emitting device 110 is improved.

In some examples, as shown in FIG. 3B, the light-emitting device 110 further includes a hole transporting layer (HTL) 146. The hole transporting layer 146 is disposed between the hole injection layer 144 and the quantum dot light-emitting layer 126.

It will be understood that the hole transporting layer 146 functions to transport holes. Therefore, the hole transporting layer 146 is disposed between the hole injection layer 144 and the quantum dot light-emitting layer 126, so that the mobility of the holes in the first electrode 122 may be improved, that is, the number of the holes in the first electrode 122 migrating into the quantum dot light-emitting layer 126 may be increased. As a result, the luminous efficiency of the light-emitting device 110 is improved.

In some examples, the hole transporting layer 146 is made of an organic material.

In some examples, as shown in FIG. 3B, the hole transporting layer 146 includes a first hole transporting layer 1461 and a second hole transporting layer 1462, and the first hole transporting layer is close to the quantum dot light-emitting layer 126 relative to second hole transporting layer 1462.

For example, a material of the first hole transporting layer 1461 includes 4,4′,4″-tris(carbazol-9-yl)triphenylamine (TCTA), and a material of the second hole transporting layer 1462 includes N,N′-bis(naphthalen-1-yl)-N,N′-bis(phenyl)benzidine (NPB).

In some examples, as shown in FIG. 3B, a thickness h6 of the first hole transporting layer 1461 is in a range of 2 nm to 20 nm, inclusive. For example, the thickness h6 of the first hole transporting layer 1461 may be in a range of 3 nm to 17 nm, inclusive, or a range of 5 nm to 10 nm, inclusive. For example, the thickness h6 of the first hole transporting layer 1461 may be 5 nm, 8 nm, 10 nm, 12 nm, or the like.

In some examples, as shown in FIG. 3B, a thickness h7 of the second hole transporting layer 1462 is in a range of 10 nm to 50 nm, inclusive. For example, the thickness h7 of the second hole transporting layer 1462 may be in a range of 15 nm to 45 nm, inclusive, or a range of 20 nm to 30 nm, inclusive. For example, the thickness h7 of the second hole transporting layer 1462 may be 20 nm, 25 nm, 30 nm, 35 nm, 45 nm, or the like.

It will be understood that the hole transporting layer 146 includes the first hole transporting layer 1461 and the second hole transporting layer 1462, the material of first hole transporting layer 1461 includes TCTA, and the material of the second hole transporting layer 1462 includes NPB. In this way, the amount of holes in first electrode 122 migrating into quantum dot light-emitting layer 126 is increased, so that the luminous efficiency of light-emitting device 110 is improved.

In addition, the thickness h6 of the first hole transporting layer 1461 is set to be in the range of 2 nm to 20 nm, inclusive, and the thickness h7 of the second hole transporting layer 1462 is set to be in the range of 10 nm to 50 nm, inclusive, it is possible to prevent the thickness of the first hole transporting layer 1461 or the second hole transporting layer 1462 from being too small (for example, the thickness of the first hole transporting layer 1461 is less than 2 nm, or the thickness of the second hole transporting layer 1462 is less than 10 nm), and prevent the thickness of the first hole transporting layer 1461 or the second hole transporting layer 1462 from being too large (for example, the thickness of the first hole transporting layer 1461 is greater than 20 nm, or the thickness of the second hole transporting layer 1462 is greater than 50 nm), so that the hole transport efficiency of the first hole transporting layer 1461 and the hole transport efficiency of the second hole transporting layer 1462 are both improved, and the number of holes in the quantum dot light-emitting layer 126 is increased. As a result, the luminous efficiency of the light-emitting device 110 is improved.

In some examples, as shown in FIG. 3C, the display panel 100 further includes a light coupling layer 148. The light coupling layer 148 is located on a side of the first electrode 122 away from the hole injection layer 144.

For example, a refractive index of the light coupling layer 148 is different from a refractive index of the first electrode 122. In some examples, the refractive index of the light coupling layer 148 is greater than the refractive index of the first electrode 122.

The light can pass through the first electrode 122 to be emitted outwards. Therefore, the refractive index of the light coupling layer 148 is greater than the refractive index of the first electrode 122, so that the light passing through the first electrode 122 may enter the light coupling layer 148 and is emitted from the light-emitting device 110 passing through the light coupling layer 148. Thus, it is possible to avoid the total reflection of the light at a contact surface of the first electrode 122 and the light coupling layer 148, thereby improving the light extraction efficiency of the light-emitting device 110, and improving the utilization rate of the light. As a result, the luminance of the light-emitting device 110 is increased, and the power consumption of the display panel 100 is reduced.

In some examples, a material of light coupling layer 148 includes NPB.

In some examples, a thickness h9 of the light coupling layer 148 is in a range of 40 nm to 80 nm, inclusive. For example, the thickness of the light coupling layer 148 may be in a range of 50 nm to 70 nm, inclusive, or a range of 55 nm to 65 nm, inclusive. For example, the thickness of the light coupling layer 148 may be 55 nm, 60 nm, 70 nm, 75 nm, or the like.

It will be understood that the thickness h9 of the light coupling layer 148 is set to be in the range of 40 nm to 80 nm, inclusive, it is possible to prevent the thickness of the light coupling layer 148 from being too small (e.g., less than 40 nm) or too large (e.g., greater than 80 nm), so that the light extraction efficiency of the light-emitting device 110 is improved. As a result, the luminance of the light-emitting device 110 is increased, and the power consumption of the display panel 100 is reduced.

It can be seen from the above, the holes in the first electrode 122 and the electrons in the second electrode 124 are transferred to the quantum dot light-emitting layer 126, and recombine in the quantum dot light-emitting layer 126 to emit light. However, the mobility of electrons is generally greater than the mobility of holes in the light-emitting device 110, resulting in an imbalance in the transport of electrons and holes, so that the number of the electrons is greater than the number of the holes in the quantum dot light-emitting layer 126.

It will be understood that the number of electrons is greater than the number of holes in the quantum dot light-emitting layer 126, which causes auger recombination to be produced by the electrons and holes in the quantum dot light-emitting layer 126. That is, instead of that light is emitted after the electrons and holes recombine, energy is transferred to another electron or hole by means of collision, causing the transition of the electron or hole.

It will be understood that when the auger recombination is produced by electrons and holes, the luminous efficiency of the light-emitting device 110 is reduced; furthermore, auger recombination may generate heat, it may be possible to cause the temperature of quantum dot light-emitting layer 126 to increase, which may affect the service life of the quantum dot light-emitting layer 126 and other film layers (e.g., the electron transporting layer 130 and the hole transporting layer 146) adjacent to the quantum dot light-emitting layer 126, so that the service life of light-emitting device 110 will be affected.

Based on this, as shown in FIGS. 3A to 3C, any light-emitting device 110 further includes at least two electron transporting layers 130. The at least two electron transporting layers 130 are stacked and located between the second electrode 124 and the quantum dot light-emitting layer 126.

It will be understood that the at least two electron transporting layers (ETL) 130 are used to transport electrons. Therefore, the at least two electron transporting layers 130 are stacked between the second electrode 124 and the quantum dot light-emitting layer 126, so that electrons may be transported to the quantum dot light-emitting layer 126 through the at least two electron transporting layers 130.

In this way, by changing the material or the thickness of at least one electron transporting layer 130 in the at least two electron transporting layers 130, the electron mobility or energy level of the at least one electron transporting layer 130 may be adjusted, so as to adjust the number of the electrons transmitted to the quantum dot light-emitting layer 126, so that the mobility of electrons and the mobility of holes in the light-emitting device 110 are balanced, and the consistency of the numbers of electrons and holes in the quantum dot light-emitting layer 126 are improved. As a result, it is possible to reduce the situation that auger recombination occurs between electrons and holes in quantum dot light-emitting layer 126, so that the luminous efficiency of light-emitting device 110 is improved, and the service life of light-emitting device 110 is prolonged.

It can be seen from the above, the plurality of light-emitting devices 110 includes the first light-emitting devices 112 and the second light-emitting devices 114. The first light-emitting devices 112 are each used to emit light of a first color, the second light-emitting devices 114 are each used to emit light of a second color, and a wavelength of the light of the first color is greater than a wavelength of the light of the second color.

In some embodiments, as shown in FIGS. 3A to 3C, the number of the electron transporting layers 130 in the first light-emitting device 112 is less than the number of the electron transporting layers 130 in the second light-emitting device 114.

It will be understood that the number of electrons transferred into the quantum dot light-emitting layer 126 may be adjusted by adjusting the number of the electron transporting layers 130.

Therefore, the number of the electron transporting layers 130 in the first light-emitting device 112 is set to be less than the number of the electron transporting layers 130 in the second light-emitting device 114, that is, it is possible to set the different numbers of electron transporting layers 130 in a targeted manner according to the color of the emitted light (wavelength of the emitted light) of the light-emitting device 110.

In this way, the number of electrons in the quantum dot light-emitting layer 126 in the light-emitting device 110 with a different color can be respectively adjusted, so as to improve the consistency between the number of electrons and the number of holes in the quantum dot light-emitting layer 126 in the light-emitting device 110 with a different color in a targeted manner, so that the luminous efficiency of the light-emitting device 110 with a different color can be improved in a targeted manner, and the service live of the light-emitting device 110 with a different color can be prolonged in a targeted manner.

In some examples, as shown in FIG. 3B, the display panel 100 further includes an electron injection layer (EIL) 142. The electron injection layer 142 is located between the second electrode 124 and the at least two electron transporting layers 130.

In some examples, the electron injection layer 142 is a zinc oxide (ZnO) film.

In some other examples, as shown in FIG. 3C, the light-emitting device 110 may not include the electron injection layer 142.

FIG. 3D is a diagram showing a structure of yet another display panel, in accordance with some embodiments.

In some embodiments, as shown in FIG. 3D, a sum h1 of thicknesses of the at least two electron transporting layers 130 in the first light-emitting device 112 is greater than a sum h2 of thicknesses of the at least two electron transporting layers 130 in the second light-emitting device 114.

It will be understood that, considering the first light-emitting device 112 as an example, the sum h1 of the thicknesses of the at least two electron transporting layers 130 in the first light-emitting device 112 is a sum of the thicknesses of all the electron transporting layers 130 (two, three, or more layers of the electron transporting layers 130) in the first light-emitting device 112.

It will be understood that the number of electrons transferred into the quantum dot light-emitting layer 126 may be adjusted by adjusting the sum of the thicknesses of the at least two electron transporting layers 130.

Therefore, the sum h1 of the thicknesses of the at least two electron transporting layers 130 in the first light-emitting device 112 is greater than the sum h2 of the thicknesses of the at least two electron transporting layers 130 in the second light-emitting device 114, that is, the sum of the thicknesses of the at least two electron transporting layers 130 is set to be different in a targeted manner according to the color of the emitted light (the wavelength of the emitted light) of the light-emitting device 110.

In this way, the number of electrons in the quantum dot light-emitting layer 126 in the light-emitting device 110 with a different color can be respectively adjusted, so as to improve the consistency between the number of electrons and the number of holes in the quantum dot light-emitting layer 126 in the light-emitting device 110 with a different color in a targeted manner, so that the luminous efficiency of the light-emitting device 110 with a different color can be improved in a targeted manner, and the service live of the light-emitting device 110 with a different color can be prolonged in a targeted manner.

FIG. 4 is a curve graph showing a variation of luminance of a light-emitting device with a sum of thicknesses of electron transporting layers, in accordance with some embodiments.

For example, in the embodiments of the present disclosure, the variation of the luminance of the light-emitting device 110 (that is, an luminous intensity of the light-emitting device 110 at the side away from the driving backboard 150) with the sum of the thicknesses of the at least two electron transporting layers 130 is simulated by taking an example in which the material of the second electrode 124 is ITO, and the thickness of the second electrode 124 is 70 nm; the thickness of the quantum dot light-emitting layer 126 is 30 nm; the material of the first hole transporting layer 1461 is TCTA, and the thickness of the first hole transporting layer 1461 is 10 nm; the material of the second hole transporting layer 1462 is NPB, and the thickness of the second hole transporting layer 1462 is 30 nm; the material of the hole injection layer 144 is MoO₃, and the thickness of the hole injection layer 144 is 7 nm; the material of the first electrode 122 is Mg and Ag (the mass ratio of Mg to Ag is 2:8), and the thickness of the first electrode 122 is 10 nm; the at least two electron transporting layers 130 are both ZnO films.

It will be noted that, in FIG. 4, the abscissa is the sum of the thicknesses of the at least two electron transporting layers 130 in nm, and the ordinate is the luminance of the light-emitting device 110 in candela per square meter (cd/m²).

It will be understood that, since the at least two electron transporting layers 130 are all ZnO films, the at least two electron transporting layers 130 may be regarded as one electron transporting layer 130.

As shown in FIG. 4, a curve a (shown by a dotted line) is a variation curve of the luminous intensity of the first light-emitting device 112 at the front with the sum of the thicknesses of the at least two electron transporting layers 130 (i.e., the thickness of the ZnO film), and a curve b (shown by a solid line) is a variation curve of the luminous intensity of the second light-emitting device 114 at the front with the sum of the thicknesses of the at least two electron transporting layers 130 (i.e., the thickness of the ZnO film).

It can be seen from FIG. 4, as for the first light-emitting device 112 and the second light-emitting device 114, the variation curve of the luminous intensity at the front with the sum of the thicknesses of the at least two electron transporting layers 130 is not the same. As shown by the curve a in FIG. 4, in a case where the thickness of the ZnO film is approximately 45 nm and approximately 190 nm, the luminous intensity of the first light-emitting device 112 at the front is high. As shown by the curve b in FIG. 4, in a case where the thickness of the ZnO film is approximately 20 nm and approximately 150 nm, the luminous intensity of the second light-emitting device 114 at the front is high.

However, the thickness of the ZnO film (i.e., the sum of the thicknesses of the at least two electron transporting layers 130) is too large or too small, which will affect electrical properties of the light-emitting device 110.

For example, the thickness of the ZnO film is too small, which may cause the current of the light-emitting device 110 to be too large, and the current efficiency (the current efficiency is equal to the luminance divide by the current density) to be decreased. On the contrary, the thickness of the ZnO film is too large, which may cause the turn-on voltage of the light-emitting device to be increased, the current to be decreased, and the luminance to be reduced, so that the performance of the light-emitting device 110 is affected.

Therefore, it is necessary to combine the optical properties and the electrical properties of the light-emitting device 110 to set the sum of the thicknesses of the at least two electron transporting layers 130.

In some embodiments, the sum of the thicknesses of the at least two electron transporting layers 130 is in a range of 5 nm to 150 nm, inclusive.

It will be understood that, in the at least two electron transporting layers 130, the thickness of each electron transporting layer 130 may be the same or different.

In some examples, the sum of the thicknesses of the at least two electron transporting layers 130 is in a range of 10 nm to 130 nm, inclusive, a range of 20 nm to 120 nm, inclusive, a range of 50 nm to 100 nm, inclusive, or the like. For example, the sum of the thicknesses of the at least two electron transporting layers 130 may be 20 nm, 50 nm, 70 nm, 90 nm, 130 nm, or the like.

It will be understood that the sum of the thicknesses of the at least two electron transporting layers 130 is set to be in a range of 5 nm to 150 nm, inclusive, so that it is possible to prevent the current of the light-emitting device 110 from being too large and the current efficiency from being reduced that caused by a fact that the sum of the thicknesses of the at least two electron transporting layers 130 is too small (e.g., less than 5 nm). In addition, it is also possible to prevent the performance of the light-emitting device 110 form being affected caused by a fact, due to the excessive thickness (e.g., greater than 150 nm) of the at least two electron transporting layers 130, that the turn-on voltage of the light-emitting device 110 from being increased, the current from being reduced and the luminance from being reduced.

It will be understood that the sum of the thicknesses of the at least two electron transporting layers 130 is set to be in a range of 5 nm to 150 nm, inclusive, so that different usage requirements may be met on the basis of improving the luminous efficiency of the light-emitting device 110.

In some embodiments, the sum of the thicknesses of the at least two electron transporting layers 130 is in a range of 20 nm to 70 nm, inclusive.

In some examples, the sum of the thicknesses of the at least two electron transporting layers 130 is in a range of 25 nm to 65 nm, inclusive, a range of 30 nm to 60 nm, inclusive, a range of 40 nm to 55 nm, inclusive, a range of 45 nm to 50 nm, inclusive, or the like. For example, the thickness of the at least two electron transporting layers 130 may be 35 nm, 45 nm, 55 nm, 65 nm, or the like.

It will be understood that the sum of the thicknesses of the at least two electron transporting layers 130 is set to be in the range of 20 nm to 70 nm, inclusive, so that it is possible to prevent the current of the light-emitting device 110 from being too large and the current efficiency from being reduced that caused by a fact that the sum of the thicknesses of the at least two electron transporting layers 130 is too small (e.g., less than 20 nm). In addition, it is also possible to prevent the performance of the light-emitting device 110 form being affected caused by a fact, due to the excessive thickness (e.g., greater than 70 nm) of the at least two electron transporting layers 130, that the turn-on voltage of the light-emitting device 110 from being increased, the current from being reduced and the luminance from being reduced.

That is, the sum of the thicknesses of the at least two electron transporting layers 130 is set to be in the range of 20 nm to 70 nm, inclusive, so that the optical properties and the electrical properties of the light-emitting device 110 are combined to improve the luminous efficiency of the light-emitting device 110.

In some embodiments, the sum of the thicknesses of the at least two electron transporting layers 130 is in a range of 20 nm to 60 nm, inclusive.

In some examples, the sum of the thicknesses of the at least two electron transporting layers 130 is in a range of 25 nm to 55 nm, inclusive, a range of 30 nm to 50 nm, inclusive, a range of 35 nm to 45 nm, inclusive, or the like. For example, the thickness of the at least two electron transporting layers 130 may be 22 nm, 30 nm, 35 nm, 45 nm, 55 nm, or the like.

It will be understood that the sum of the thicknesses of the at least two electron transporting layers 130 is set to be in the range of 20 nm to 60 nm, inclusive, so that it is possible to prevent the current of the light-emitting device 110 from being too large and the current efficiency from being reduced that caused by a fact that the sum of the thicknesses of the at least two electron transporting layers 130 is too small (e.g., less than 20 nm). In addition, it is also possible to prevent the performance of the light-emitting device 110 form being affected caused by a fact that the turn-on voltage of the light-emitting device 110 from being increased, the current from being reduced and the luminance from being reduced that due to the excessive thickness (e.g., greater than 60 nm) of the at least two electron transporting layers 130.

That is, the sum of the thicknesses of the at least two electron transporting layers 130 is set to be in the range of 20 nm to 60 nm, inclusive, so that the optical properties and the electrical properties of the light-emitting device 110 are combined to improve the luminous efficiency of the light-emitting device 110.

It can be seen from the above, the display panel 100 further includes the driving backplate 150, and the plurality of light-emitting devices 110 are located on a side of the driving backplate 150. Moreover, the light-emitting device 110 is of an inverted structure, i.e., the first electrode 122 is far away from the driving backplate 150 relative to the second electrode 124.

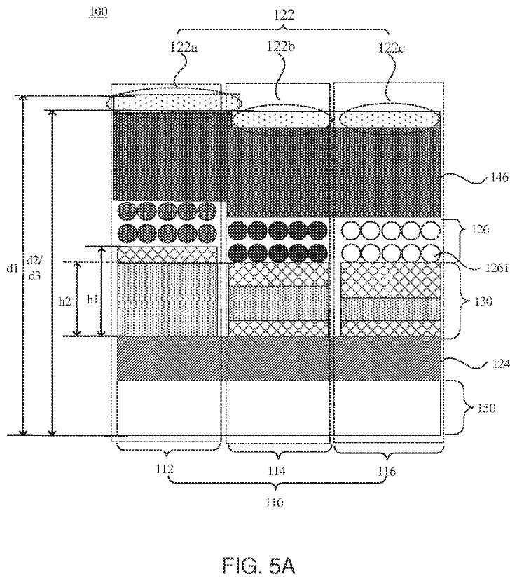

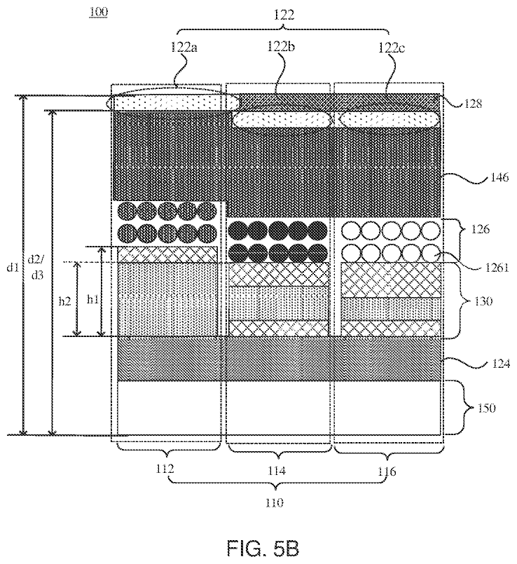

FIG. 5A is a diagram showing a structure of yet another display panel, in accordance with some embodiments.

In some embodiments, as shown in FIG. 5A, the first light-emitting device 112 includes a first first electrode 122a, and the second light-emitting device 114 includes a second first electrode 122b. A distance d1 between a surface of the first first electrode 122a away from the driving backplate 150 and the driving backplate 150 is greater than a distance d2 between a surface of the second first electrode 122b away from the driving backplate 150 and the driving backplate 150.

For example, the first electrodes 122 of the plurality of light-emitting devices 110 (including the first light-emitting devices 112 and the second light-emitting devices 114) constitute a whole-layer structure. The first first electrode 122a and the second first electrode 122b are a portion of the whole-layer structure of the first electrodes 122.

As shown in FIG. 5A, the sum h1 of the thicknesses of the at least two electron transporting layers 130 in the first light-emitting device 112 is greater than the sum h2 of the thicknesses of the at least two electron transporting layers 130 in the second light-emitting device 114, so that the distance d1 between the surface of the first first electrode 122a away from the driving back plate 150 and the driving back plate 150 can be greater than the distance d2 between the surface of the second first electrode 122b away from the driving back plate 150 and the driving back plate 150.

It will be understood that, in the embodiments of the present disclosure, considering the first first electrode 122a as an example, the distance d1 between the surface of the first first electrode 122a away from the driving backplate 150 and the driving backplate 150 is a distance between the surface of the first first electrode 122a away from the driving backplate 150 and a film layer (e.g., the driving circuit layer 158) in the driving backplate 150 farthest from the substrate 152.

With this arrangement, on the basis of improving the consistency of the number of electrons and the number of holes in the quantum dot light-emitting layer 126 in the light-emitting devices 110 with different colors, the thicknesses of the first electrodes 122 (e.g., the first first electrode 122a and the second first electrode 122b) of different light-emitting devices 110 may be the same or approximately the same (that is, the whole-layer structure of the first electrodes 122 has a same or approximately same thickness at different positions), so that the consistency of the number of holes transmitted from the first electrode 122 to the quantum dot light-emitting layer 126 in different light-emitting devices 110 is improved, and the reliability of the plurality of light-emitting devices 110 is improved.

It will be understood that, in some other examples, in a case where the light-emitting device 110 is of an upright structure, (that is, the first electrode 122 is close to the driving back plate 150 relative to the second electrode 124), similarly, the first light-emitting device 112 includes a first second electrode, and the second light-emitting device 114 includes a second second electrode, and a distance between a surface of the first second electrode away from the driving backplate 150 and the driving backplate 150 is greater than a distance between a surface of the second second electrode away from the driving backplate 150 and the driving backplate.

FIG. 5B is a diagram showing a structure of yet another display panel, in accordance with some embodiments.

In some other examples, as shown in FIG. 5B, the display panel 100 further includes a filling layer 128. The filling layer 128 is located at least on a surface of the second first electrode 122b away from the driving backplate 150. Moreover, a surface of the filling layer 128 away from the driving backplate 150 is flush or substantially flush with the surface of the first first electrode 122a away from the driving backplate 150, so that the structural regularity of the light-emitting devices 110 is improved.

In some examples, a material of the filling layer 128 may include silicon oxide or silicon nitride.

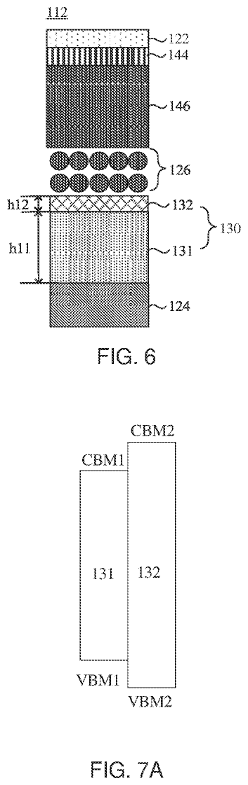

FIG. 6 is a diagram showing a structure of a first light-emitting device, in accordance with some embodiments.

In some embodiments, as shown in FIG. 6, the at least two electron transporting layers 130 of the first light-emitting device 112 include a first electron transporting layer 131 and a second electron transporting layer 132. An electron mobility of the second electron transporting layer 132 is less than an electron mobility of the first electron transporting layer 131.

In some examples, as shown in FIG. 6, the first electron transporting layer 131 is close to the second electrode 124 relative to the second electron transporting layer 132. In some other examples, the first electron transporting layer 131 is far away from the second electrode 124 relative to the second electron transporting layer 132.

It will be understood that the electron mobility of the second electron transporting layer 132 is set to be smaller than the electron mobility of the first electron transporting layer 131, which can reduce the electron mobility of the at least two electron transporting layers 130 as a whole, so that the number of electrons in the quantum dot light-emitting layer 126 is reduced, and the consistency of the number of electrons and the number of holes in the quantum dot light-emitting layer 126 is improved. As a result, the luminous efficiency of the light-emitting device 110 is improved.

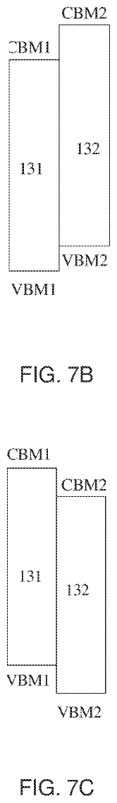

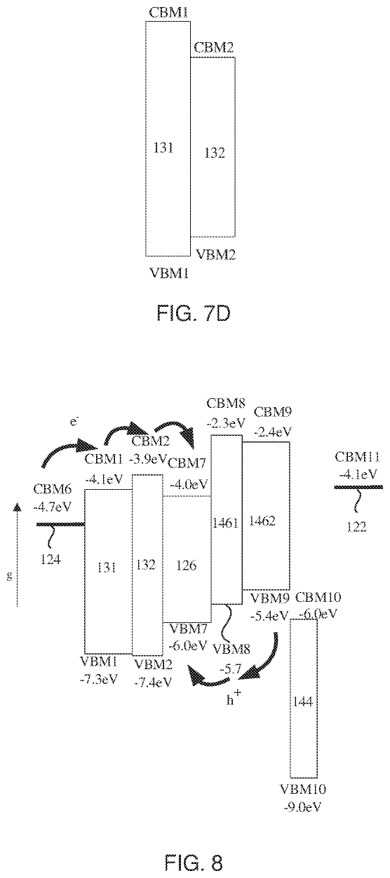

FIG. 7A is a diagram showing an energy level relationship of the first electron transporting layer and the second electron transporting layer, in accordance with some embodiments. FIG. 7B is a diagram showing an energy level relationship of the first electron transporting layer and the second electron transporting layer, in accordance with some other embodiments. FIG. 7C is a diagram showing an energy level relationship of the first electron transporting layer and the second electron transporting layer, in accordance with yet some other embodiments. FIG. 7D is a diagram showing an energy level relationship of the first electron transporting layer and the second electron transporting layer, in accordance with yet some other embodiments.

In some examples, as shown in FIGS. 7A to 7D, an energy of the conduction band minimum (CBM) CBM1 of the first electron transporting layer 131 is different from an energy of the conduction band minimum CBM2 of the second electron transporting layer 132.

In this way, an electron transporting barrier may be formed between the first electron transporting layer 131 and the second electron transporting layer 132, which blocks the transmission of electrons to the quantum dot light-emitting layer 126, reduces the number of electrons in the quantum dot light-emitting layer 126, and increases the consistency of the number of electrons and the number of holes in the quantum dot light-emitting layer 126, thereby improving the luminous efficiency of the light-emitting device 110.

In some examples, as shown in FIG. 6, the first electron transporting layer 131 is close to the second electrode 124 relative to the second electron transporting layer 132. In this case, the energy of the conduction band minimum CBM1 of the first electron transporting layer 131 is less than the energy of the conduction band minimum CBM2 of the second electron transporting layer 132.

That is, as shown in FIGS. 7A and 7B, in a case where the first electron transporting layer 131 is close to the second electrode 124 relative to the second electron transporting layer 132, the energy of the conduction band minimum CBM1 of the first electron transporting layer 131 is less than the energy of the conduction band minimum CBM2 of the second electron transporting layer 132, so that an electron transporting barrier may be formed between the first electron transporting layer 131 and the second electron transporting layer 132. As a result, the transmission of the electrons to the quantum dot light-emitting layer 126 is blocked, the number of electrons in the quantum dot light-emitting layer 126 is reduced, and the consistency of the number of electrons and the number of holes in the quantum dot light-emitting layer 126 is increased, thereby improving the luminous efficiency of the light-emitting device 110.

In some examples, as shown in FIG. 7A, an energy of a valence band maximum (VBM) VBM1 of the first electron transporting layer 131 is greater than an energy of a valence band maximum VBM2 of the second electron transporting layer 132. In some other examples, as shown in FIG. 7B, the energy of the valence band maximum VBM1 of the first electron transporting layer 131 is less than the energy of the valence band maximum VBM2 of the second electron transporting layer 132.

In some other examples, the first electron transporting layer 131 is far away from the second electrode 124 relative to the second electron transporting layer 132. In this case, the energy of the conduction band minimum CBM1 of the first electron transporting layer 131 is greater than the energy of the conduction band minimum CBM2 of the second electron transporting layer 132.

That is, as shown in FIGS. 7C and 7D, in a case where the first electron transporting layer 131 is far away from the second electrode 124 relative to the second electron transporting layer 132, the energy of the conduction band minimum CBM1 of the first electron transporting layer 131 is greater than the energy of the conduction band minimum CBM2 of the second electron transporting layer 132, so that an electron transporting barrier may be formed between the first electron transporting layer 131 and the second electron transporting layer 132. As a result, the transmission of the electrons to the quantum dot light-emitting layer 126 is blocked, and the consistency of the number of electrons and the number of holes in the quantum dot light-emitting layer 126 is increased, thereby improving the luminous efficiency of the light-emitting device 110.

In some examples, as shown in FIG. 7C, the energy of the valence band maximum VBM1 of first electron transporting layer 131 is greater than the energy of the valence band maximum VBM2 of second electron transporting layer 132. In some other examples, as shown in FIG. 7B, the energy of the valence band maximum VBM1 of the first electron transporting layer 131 is less than the energy of the valence band maximum VBM2 of the second electron transporting layer 132.

FIG. 8 is a diagram showing an energy level structure of a light-emitting device, in accordance with some embodiments.

In some examples, as shown in FIG. 8, the direction represented by the arrow g is a direction in which the energy (including the energy of the valence band maximum VBM and the energy of the conduction band minimum CBM) increases. The arrow e⁻ represents the migration path of electrons, and the arrow h⁺ represents the migration path of holes.

Of the second electrode 124 of the first light-emitting device 112, a material is made of ITO, and an energy of the conduction band minimum CBM6 is −4.7 electron volts (eV).

The first electron transporting layer 131 is a ZnO film, and of the first electron transporting layer 131, the energy of the conduction band minimum CBM1 is −4.1 eV, and the energy of the valence band maximum VBM1 is −7.3 eV.

The second electron transporting layer 132 is a magnesium zinc oxide (ZnMgO) film, and of the second electron transporting layer 132, the energy of the conduction band minimum CBM2 is −3.9 eV and the energy of a valence band maximum VBM2 is −7.4 eV.

Of the red quantum dot (RQD) light-emitting layer, a material is CdSe-based quantum dot material, an energy of the conduction band minimum CBM7 is-4.0 eV, and an energy of the valence band maximum VBM7 is −6.0 eV.

The first hole transporting layer 1461 is a TCTA film, and of the first hole transporting layer 1461, an energy of a conduction band minimum CBM8 is −2.3 eV, and an energy of a valence band maximum VBM8 is −5.7 eV.

The second hole transporting layer 1462 is an NPB film, an energy of a conduction band minimum CBM9 is −2.4 eV, and an energy of a valence band maximum VBM9 is −5.4 eV.

The hole injection layer 144 is a MoO₃ film, and of the hole injection layer 144, an energy of a conduction band minimum CBM10 is −6.0 eV, and an energy of a valence band maximum VBM10 is −9.0 eV.

Of the first electrode 122, a material includes Mg and Ag (the mass ratio of Mg to Ag is 2:8), and an energy of a conduction band minimum CBM11 is −4.1 eV.

In some embodiments, a material of the first electron transporting layer 131 includes any one of ZnO, gallium zinc oxide (GZO), aluminum zinc oxide (AZO), indium zinc oxide (IZO), indium gallium zinc oxide (IGZO), and magnesium zinc oxide (ZnMgO); a material of the second electron transporting layer 132 includes any one of ZnO, GZO, AZO, IZO, IGZO, and ZnMgO; the material of the first electron transporting layer 131 is different from the material of the second electron transporting layer 131.

In this way, the electron mobility of the second electron transporting layer 132 may be smaller than the electron mobility of the first electron transporting layer 131, so that an electron transport barrier may be formed between the first electron transporting layer 131 and the second electron transporting layer 132. As a result, the transmission of the electrons to the quantum dot light-emitting layer 126 is blocked, and the consistency of the number of electrons and the number of holes in the quantum dot light-emitting layer 126 is increased, thereby improving the luminous efficiency of the light-emitting device 110.

It will be understood that the first electron transporting layer 131 and the second electron transporting layer 132 may be other n-type oxide films.

In some examples, in a case where the first electron transporting layer 131 is close to the quantum dot light-emitting layer 126 relative to the second electron transporting layer 132, the material of first electron transporting layer 131 includes ZnO, and the material of the second electron transporting layer includes ZnMgO.

It can be seen from the above, the sum of the thicknesses of the at least two electron transporting layers 130 affects the number of electrons in the quantum dot light-emitting layer 126. It will be understood that the thickness of each electron transporting layer 130 of the at least two electron transporting layers 130 will have an effect on the number of electrons in the quantum dot light-emitting layer 126.

In some embodiments, as shown in FIG. 6, the thickness h11 of the first electron transporting layer 131 is greater than 0 nm and less than or equal to 60 nm; and/or, the thickness h12 of the second electron transporting layer 132 is greater than 0 nm and less than or equal to 60 nm. Moreover, the thickness h11 of the first electron transporting layer 131 is greater than the thickness h12 of the second electron transporting layer 132.

In some examples, the thickness h11 of the first electron transporting layer 131 is greater than 0 nm and less than or equal to 55 nm. In some other examples, the thickness h11 of the first electron transporting layer 131 is greater than 0 nm and less than or equal to 45 nm. In yet some other examples, the thickness h11 of the first electron transporting layer 131 is greater than 0 nm and less than or equal to 35 nm.

For example, the thickness h11 of the first electron transporting layer 131 may be 15 nm, 25 nm, 35 nm, 45 nm, or the like.

In some examples, the thickness h12 of the second electron transporting layer 132 is greater than 0 nm and less than or equal to 55 nm. In some other examples, the thickness h12 of the second electron transporting layer 132 is greater than 0 nm and less than or equal to 45 nm. In yet some other examples, the thickness h12 of the second electron transporting layer 132 is greater than 0 nm and less than or equal to 35 nm.

For example, the thickness h12 of the second electron transporting layer 132 may be 15 nm, 25 nm, 35 nm, 45 nm, or the like.

The thickness h11 of the first electron transporting layer 131 is set to be greater than 0 nm and less than or equal to 60 nm, and the thickness h12 of the second electron transporting layer 132 is set to be greater than 0 nm and less than or equal to 60 nm, so that it is possible to prevent the performance of the light-emitting device 110 form being affected caused by a fact, due to the excessive thickness of the first electron transporting layer 131 and the second electron transporting layer 132 (for example, the thickness of the first electron transporting layer 131 or the second electron transporting layer 132 is greater than 60 nm), that the turn-on voltage of the light-emitting device 110 from being increased, the current from being reduced and the luminance from being reduced.

Moreover, the thickness of the first electron transporting layer 131 and the second electron transporting layer 132 is prevented from being too large (for example, the thickness of the first electron transporting layer 131 or the thickness of the second electron transporting layer 132 is greater than 60 nm), so that it is possible to increase the luminous intensity of the first light-emitting device 112 at the front (away from the driving backplate 150), and reduce the luminous intensity of the first light-emitting device 112 at the side. As a result, the light extraction efficiency of the first light-emitting device 112 is improved, the luminance of the first light-emitting device 112 is increased, and the power consumption of the display panel 100 is reduced.

In addition, the thickness h11 of the first electron transporting layer 131 is set to be greater than the thickness h12 of the second electron transporting layer 132, so that it is possible to prevent the performance of the first light-emitting device 112 form being affected caused by a fact, due to the overlarge sum of the thicknesses of the at least two electron transporting layers 130, that the turn-on voltage of the first light-emitting device 112 from being increased, the current from being reduced and the luminance from being reduced. In some embodiments, the thickness of the first electron transporting layer 131 is in a range of 30 nm to 50 nm, inclusive; and/or, a thickness of the second electron transporting layer 132 is in a range of 1 nm to 30 nm, inclusive.

In some examples, a thickness h11 of the first electron transporting layer 131 is in a range of 35 nm to 45 nm, inclusive, or a range of 30 nm to 40 nm, inclusive. For example, the thickness h11 of the first electron transporting layer 131 may be 35 nm, 40 nm, 45 nm, or the like.

In some examples, a thickness h12 of the second electron transporting layer 132 is in a range of 5 nm to 25 nm, inclusive, or a range of 10 nm to 20 nm, inclusive. For example, the thickness h12 of the second electron transporting layer 132 may be 5 nm, 10 nm, 15 nm, 20 nm, or the like.

The thickness h11 of the first electron transporting layer 131 is set to be in the range of 30 nm to 50 nm, inclusive, and the thickness of the second electron transporting layer 132 is set to be in the range of 1 nm to 30 nm, inclusive, so that it is possible to prevent the current efficiency of the first light-emitting device 112 from being reduced caused by an overlarge current of the first light-emitting device 112 due to a fact that the thickness h11 of the first electron transporting layer 131 or the thickness h12 of the second electron transporting layer 132 is too small (for example, the thickness h11 of the first electron transporting layer 131 is less than 30 nm, and the thickness of the second electron transporting layer 132 is less than 1 nm).

Moreover, it is possible to prevent the performance of the first light-emitting device 112 form being affected caused by a fact, due to the excessive thickness h11 of the first electron transporting layer 131 and the excessive thickness h12 of the second electron transporting layer 132 (for example, the thickness h11 of the first electron transporting layer 131 is greater than 50 nm, or the thickness of the second electron transporting layer 132 is greater than 30 nm), that the turn-on voltage of the first light-emitting device 112 from being increased, the current from being reduced and the luminance from being reduced.

In addition, the thickness h11 of the first electron transporting layer 131 or the thickness h12 of the second electron transporting layer 132 is prevented from being too large (for example, the thickness h11 of the first electron transporting layer 131 is greater than 50 nm, or the thickness of the second electron transporting layer 132 is greater than 30 nm), so that it is possible to increase the luminous intensity of the first light-emitting device 112 at the front (away from the driving backplate 150), and reduce the luminous intensity of the first light-emitting device 112 at the side. As a result, the light extraction efficiency of the first light-emitting device 112 is improved, and the luminance of the first light-emitting device 112 is increased, so that the power consumption of the display panel 100 is reduced.

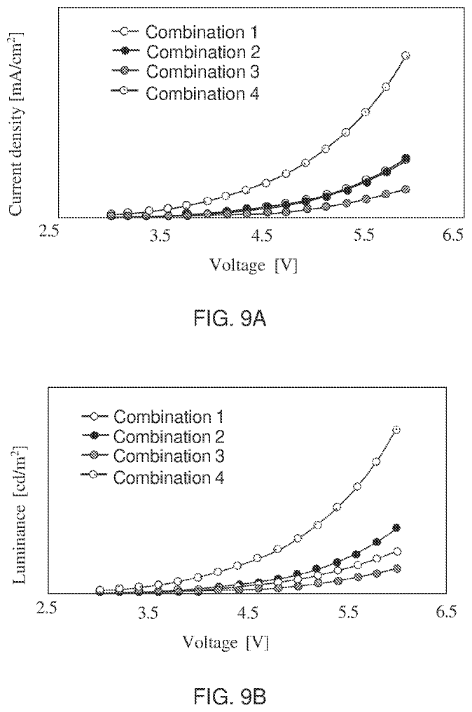

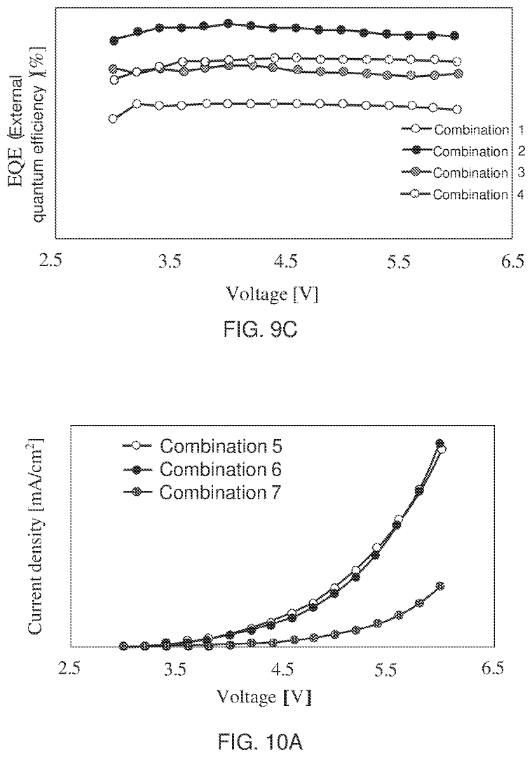

FIG. 9A is a curve graph showing a variation of a current density with a voltage, in accordance with some embodiments. FIG. 9B is a curve graph showing a variation of the luminance with a voltage, in accordance with some embodiments. FIG. 9C is a curve graph showing a variation of an external quantum efficiency with a voltage, in accordance with some embodiments.

Referring to FIGS. 9A to 9C, in some embodiments of the present disclosure, the current density, the luminance, and the external quantum efficiency of the first light-emitting device 112 are illustrated in a case where the first electron transporting layer 131 and the second electron transporting layer 132 in the first light-emitting device 112 have different thicknesses.

It will be noted that, in FIG. 9A, the abscissa represents voltage in V, and the ordinate represents current density in mA/cm²; in FIG. 9B, the abscissa is voltage in V, and the ordinate is luminance in candela per square meter (cd/m²); in FIG. 9C, the abscissa represents voltage in V, and the ordinate represents the external quantum efficiency (EQE). It will be understood that, EQE is equal to the number of the emitted photons divide by the number of the injected holes. The greater the EQE, the better the light emission performance of the light-emitting device 110.

As shown in FIGS. 9A to 9C, Combinations 1 to 4 are combinations of electron transporting layers 130 of different thicknesses and materials.

In Combination 1, the materials of the at least two electron transporting layers 130 are all ZnO (which may also be regarded as one electron transporting layer 130), and the thickness of the ZnO film is 60 nm.

In Combination 2, of the first electron transporting layer 131, the material is ZnO, and a thickness is 45 nm; of the second electron transporting layer 132, the material is ZnMgO, and a thickness is 15 nm.

In Combination 3, of the first electron transporting layer 131, the material is ZnO, and a thickness is 30 nm; of the second electron transporting layer 132, the material is ZnMgO, and a thickness is 30 nm.

In combination 4, of the first electron transporting layer 131, the material is ZnMgO, and a thickness is 15 nm; of the second electron transporting layer 132, the material is ZnO, and a thickness is 45 nm.

For example, a molar percentage of Mg in ZnMgO in Combination 2, Combination 3, and Combination 4 is 5%.

As shown in FIGS. 9A to 9C, as for the first light-emitting device 112 having two electron transporting layers 130 (such as Combination 2, Combination 3, and Combination 4, which includes the first electron transporting layer 131 and the second electron transporting layer 132), the current density, the luminance, and the EQE are all better than those of the first light-emitting device 112 having a single electron transporting layer 130 (Combination 1). That is, in a case where two electron transporting layers 130 are included, the first light-emitting device 112 may have a good light emission performance.

It will be understood that, in a case where two electron transporting layers 130 are included, at least one of the first electron transporting layer 131 and the second electron transporting layer 132 is made of ZnMgO. In this way, it is possible to block electrons by doping with Mg ions, so that the electron mobility of the first electron transporting layer 131 or the second electron transporting layer 132 is reduced. As a result, the number of the electrons in the quantum dot light-emitting layer 126 is reduced, and the consistency of the number of electrons and the number of holes in the quantum dot light-emitting layer 126 is improved, thereby improving the luminous efficiency of the first light-emitting device 112.

In addition, in a case where the material of the first electron transporting layer 131 is ZnO, and the material of the second electron transporting layer 132 is ZnMgO, an energy difference may be formed between the first electron transporting layer 131 and the second electron transporting layer 132, so that an electron transport barrier is formed. In this way, the transmission of the electrons to the quantum dot light-emitting layer 126 is blocked, and the consistency of the number of electrons and the transporting ability of electrons and the transporting ability of holes in the first light-emitting device 112 is balanced, thereby improving the luminous efficiency of the light-emitting device 110.

As shown in FIGS. 9A and 9B, in a case where the voltage is increased, the luminance of the first light-emitting device 112 including Combination 2 is increased, but the current density variation is small, so that the current efficiency (current efficiency is equal to the luminance divide by the current density) may be increased. In addition, as shown in FIG. 9C, in a case where Combination 2 is included, the external quantum efficiency EQE of the first light-emitting device 112 is increased, so that the performance of the first light-emitting device 112 is improved.

As shown in FIGS. 9A and 9B, in a case where the voltage is increased, the luminance of the first light-emitting device 112 including Combination 3 is small, and the current density variation is small, so that the current efficiency may be small. In addition, as shown in FIG. 9C, in a case where Combination 3 is included, the external quantum efficiency EQE of the first light-emitting device 112 is small, so that the performance of the first light-emitting device 112 is affected.

As shown in FIGS. 9A and 9B, in a case where the voltage is increased, the current density and luminance of the first light-emitting device 112 including Combination 4 are both increased, so that the current efficiency may be reduced. In addition, as shown in FIG. 9C, in a case where Combination 4 is included, the external quantum efficiency EQE of the first light-emitting device 112 is small, so that the performance of the first light-emitting device 112 is affected.

That is, in a case where the thickness of the ZnMgO film is increased from 20 nm to 40 nm, the current of the first light-emitting device 112 is reduced, and the luminance is also reduced, so that the performance of the first light-emitting device 112 is lower than that of the first light-emitting device 112 including Combination 2 (in which the material of the first electron transmitting layer 131 is ZnO and a thickness is 45 nm, and the material of the second electron transit layer 132 is ZnMgO and a thickness is 15 nm).

Thus, in some embodiments, the thickness of first electron transporting layer 131 is approximately 45 nm; and/or the thickness of the second electron transporting layer 132 is approximately 15 nm.

It can be seen form the above, with this configuration, the current efficiency and the external quantum efficiency of the first light-emitting device 112 may be improved, so that the light emission performance of the first light-emitting device 112 may be improved.

It will be understood that “approximately” includes a stated value and an average value within an acceptable range of deviation of a particular value determined by a person of ordinary skilled in the art, considering measurement in question and errors associated with measurement of a particular quantity (i.e., limitations of a measurement system).

Considering the first electron transporting layer 131 as an example, the thickness of the first electron transporting layer 131 is approximately 45 nm. That is, the thickness of the first electron transporting layer 131 is 45 nm, and the deviation within a certain range (for example, within 3% or within 5% or the like) may be accepted on the basis of 45 nm.

It can be seen form the above, the material of the second electron transporting layer 132 includes ZnMgO. In some embodiments, in the second electron transporting layer 132, a molar percentage of magnesium (Mg) is greater than 0 and less than or equal to 50%, and a sum of the molar percentage of Mg and a molar percentage of zinc (Zn) is 1.

It will be understood, the material of the second electron transporting layer 132 includes Zn_{1-X}Mg_{X}O, where X is the molar percentage of Mg and (1-X) is the molar percentage of Zn.

It will be understood that, by adjusting the molar percentage of Mg in the second electron transporting layer 132, the electron mobility of the second electron transporting layer 132 and the energies (for example, the energy of the valence band maximum VBM and the energy of the conduction band minimum CBM) of the second electron transporting layer 132 may be adjusted, so that the number of electrons transferred into the quantum dot light-emitting layer 126 may be adjusted, and the transport balance of electrons and holes in the first light-emitting device 112 may be improved, and thus the luminous efficiency of the first light-emitting device 112 is improved.

In some examples, the molar percentage of Mg is greater than 0, and less than or equal to 40%. In some other examples, the molar percentage of Mg is greater than 0, and less than or equal to 30%. In yet some other examples, the molar percentage of Mg is greater than 0, and less than or equal to 20%.

For example, the molar percentage of Mg in the second electron transporting layer 132 may be 10%, 20%, 30%, 40%, or the like.

It will be understood that in a case where the molar percentage of Mg is greater than 0 and less than or equal to 50% in the second electron transporting layer 132, the molar percentage of Zn is greater than or equal to 50% and less than 100%.

In some embodiments, the molar percentage of Mg in the second electron transporting layer 132 is in a range of 1% to 20%, inclusive.

In some examples, the molar percentage of Mg in the second electron transporting layer 132 may be in a range of 2% to 20%, inclusive, a range of 5% to 15%, inclusive, a range of 7% to 12%, inclusive, or the like. For example, the molar percentage of Mg in the second electron transporting layer 132 may be 5%, 8%, 10%, 15%, or the like.

It will be understood that, by adjusting the molar percentage of Mg in the second electron transporting layer 132, the electron mobility of the second electron transporting layer 132 and the energies (e.g., the energy of the valence band maximum VBM and the energy of the conduction band minimum CBM) of the second electron transporting layer 132 may be adjusted, so that the number of electrons transferred into the quantum dot light-emitting layer 126 may be adjusted, and the transport balance of electrons and holes in the first light-emitting device 112 may be improved, and thus the luminous efficiency of the first light-emitting device 112 is improved.

It will be understood that, in a case where the molar percentage of Mg in the second electron transporting layer 132 is in a range of 1% to 20%, inclusive, the molar percentage of Zn is in a range of 80% to 99%, inclusive.

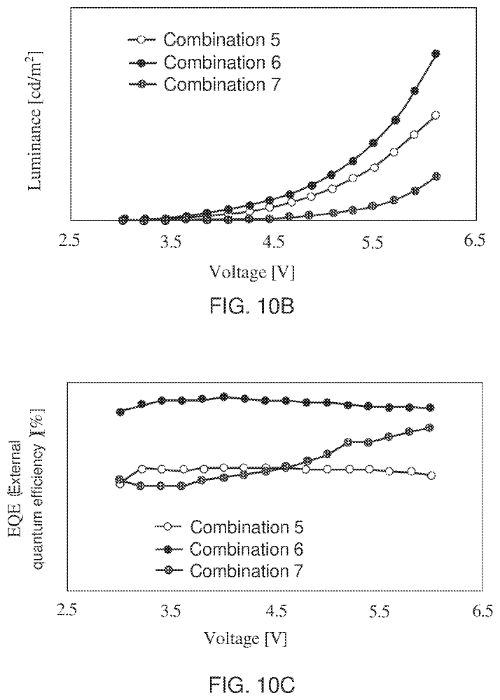

FIG. 10A is curve graph showing a variation of a current density with a voltage, in accordance with yet some other embodiments. FIG. 10B is a curve graph showing a variation of a luminance with a voltage, in accordance with some embodiments. FIG. 10C is a curve graph showing a variation of an external quantum efficiency with a voltage, in accordance with some other embodiments.

Referring to FIGS. 10A to 10C, in some embodiments of the present disclosure, the current density, the luminance, and the external quantum efficiency of the first light-emitting device 112 are illustrated in a case where the molar percentage of Mg in the second electron transporting layer 132 in the first light-emitting device 112 is different.

It will be noted that in FIG. 10A, the abscissa represents voltage in V and the ordinate represents current density in mA/cm²; in FIG. 10B, the abscissa is voltage in V, and the ordinate is luminance in candela per square meter (cd/m²); in FIG. 10C, the abscissa represents voltage in V, and the ordinate represents the external quantum efficiency (EQE). It will be understood that, EQE is equal to the number of the emitted photons divide by the number of the injected holes. The greater the EQE, the better the light emission performance of the light-emitting device 110.

As shown in FIGS. 10A to 10C, Combination 5 to Combination 7 are combinations of the second electron transporting layer 132 and the first electron transporting layer 131 in which the molar percentage of Mg in the second electron transporting layer 132 is different.

In Combination 5, the at least two electron transporting layers 130 are all a ZnO film (which may also be regarded as one electron transporting layer 130), and the thickness of the ZnO film is 60 nm.

The first electron transporting layer 131 in Combination 6 is a ZnO film with a thickness of 45 nm. The second electron transporting layer 132 is a ZnMgO film with a thickness of 15 nm, and the molar percentage of Mg in ZnMgO is 5%.

The first electron transporting layer 131 in Combination 7 is a ZnO film with a thickness of 45 nm. The second electron transporting layer 132 is a ZnMgO film with a thickness of 15 nm, and the molar percentage of Mg in ZnMgO is 8%.

As shown in FIGS. 10A to 10C, as for the first light-emitting device 112 including two electron transporting layers 130 (such as Combination 6 or Combination 7, which includes the first electron transporting layer 131 and the second electron transporting layer 132), the current density, the luminance, and the EQE are all better than those of the first light-emitting device 112 including a single electron transporting layer 130 (Combination 5). That is, in a case where two electron transporting layers 130 are included, the first light-emitting device 112 may have a good light emission performance.

As shown in FIGS. 10A and 10B, in a case where the voltage is increased, the luminance of the first light-emitting device 112 including Combination 6 is increased. In addition, as shown in FIG. 10C, in a case where Combination 6 is included, the external quantum efficiency EQE of the first light-emitting device 112 is increased, so that the performance of the first light-emitting device 112 is improved.

As shown in FIGS. 10A and 10B, in a case where the voltage is increased, the luminance of the first light-emitting device 112 including Combination 7 is small and the current density is small, so that the current efficiency is small. In addition, as shown in FIG. 10C, in a case where Combination 7 is included, the EQE of the first light-emitting device 112 is small, which will affect the performance of the first light-emitting device 112.

It will be understood that, as shown in FIGS. 10A to 10C, in a case where the molar percentage of Mg in the second electron transporting layer 132 is increased from 5% to 8%, the current density of the first light-emitting device 112 is reduced, and the luminance is also greatly reduced, so that the current efficiency and EQE of the first light-emitting device 112 is reduced.

That is, in a case where the material of the first electron transporting layer 131 is ZnO with a thickness of 45 nm, the material of the second electron transporting layer 132 is ZnMgO with a thickness of 15 nm, and the molar percentage of Mg in ZnMgO is 5%, the first light-emitting device 112 has a good light emission performance.

Thus, in some embodiments, the molar percentage of Mg in the second electron transporting layer 132 is approximately 5%.

It can be seen form the above, with this configuration, the current efficiency and the external quantum efficiency of the first light-emitting device 112 may be improved, so that the light emission performance of the first light-emitting device 112 may be improved.

It will be understood that, in the embodiments of the present disclosure, “approximately” includes a stated value and an average value within an acceptable range of deviation of a particular value determined by a person of ordinary skilled in the art, considering measurement in question and errors associated with measurement of a particular quantity (i.e., limitations of a measurement system).

Considering the molar percentage of Mg in the second electron transporting layer 132 as an example, the molar percentage of Mg in the second electron transporting layer 132 is approximately 5%. That is, the molar percentage of Mg in the second electron transporting layer 132 is 5%, and the deviation within a certain range (for example, within 3%, within 5% or the like) can be received on the basis of 5%.

In some examples, in a case where the first electron transporting layer 131 is a ZnO film having a thickness of 45 nm, the second electron transporting layer 132 is a ZnMgO film having a thickness of 15 nm, and the molar percentage of Mg in ZnMgO is 5%, the energy level relationship between the first electron transporting layer 131 and the second electron transporting layer 132 is as shown in FIG. 7A.

For example, in a case where the second electron transporting layer 132 is a ZnO film with a thickness of 45 nm, the first electron transporting layer 131 is a ZnMgO film with a thickness of 15 nm, in which the molar percentage of Mg in ZnMgO is 5%, the energy level relationship between the first electron transporting layer 131 and the second electron transporting layer 132 is shown in FIG. 7D.

A method of manufacturing a light-emitting device 110 will be exemplified below.

In some implementations, at least two electron transporting layers 130 are formed on a side of the second electrode 124 by using a solution process generally. For example, the at least two electron transporting layers 130 are formed by using a solution process. That is, particles forming the electron transporting layers 130 are dissolved in a solvent, and then the solvent is evaporated.

In an example in which the ZnO film serves as an electron transporting layer, ZnO particles may be dissolved in ethanol, a side of the second electrode 124 may be coated (e.g., by inkjet printing) with the solvent obtained after the dissolution, and then the ethanol may be evaporated, so as to obtain the ZnO film.

The inventors of the present disclosure have found that the following technical problems exist in the above implementations.

In the ZnO film manufactured by the solvent method, a large number of surface states exist in ZnO nanoparticles, (i.e., a large number of defects exist on the surfaces of the ZnO nanoparticles). A large amount of surface states exist in the ZnO nanoparticles interact with the quantum dot light-emitting layer 126 to capture electrons in the quantum dot light-emitting layer 126, so that the luminous efficiency of the light-emitting device 110 is affected.

In addition, in a case where it is necessary to form at least two electron transporting layers 130, after an electron transporting layer 130 is formed, there is a need to continue to coat a side of the electron transporting layer 130 away from the second electrode 124 with the solvent, so as to form another electron transporting layer 130.

For convenience of description, the electron transporting layer 130 formed first is defined as a first electron transporting layer, and the electron transit layer 130 formed later is defined as a second electron transporting layer below. It will be noted that the first electron transporting layer and the second electron transporting layer are only used to distinguish the electron transporting layer 130 formed first from the electron transporting layer 130 formed later, and do not further limit the electron transporting layers 130.

It will be understood that, when the second electron transporting layer is formed, the solvent for forming the second electron transporting layer is required to be coated on the side of the formed first electron transporting layer away from the second electrode 124. Thus, when the solvent for forming the second electron transporting layer and the solvent for forming the first electron transporting layer are non-orthogonal solvents, the solvent for forming the second electron transporting layer will re-dissolve the formed first electron transporting layer, which may damage the formed first electron transporting layer, and increase the difficulty in manufacturing the at least two electron transporting layers 130.

In addition, in the ZnO film manufactured by the solvent method, ZnO is in a shape of a nano-particle. For example, the ZnO nanoparticles are approximately 5 nm in diameter. In this way, the ZnO film has a high surface roughness. In some examples, the root mean square (RMS) of the surface roughness of the ZnO film manufactured by the solvent method may reach 1 nm to 2 nm.

Moreover, the ZnO film manufactured by the solvent method is not suitable for the high-resolution display, which affects the display performance of the display panel 100.

Based on this, in the embodiments of the present disclosure, at least two electron transporting layers 130 are formed on a side of the second electrode 124 by magnetron sputtering.

The method for forming the at least two electron transporting layers 130 will be described by taking an example in which the second electrode 124 is an ITO substrate below.

In some examples, the first electron transporting layer 131 may be formed by means of single-target sputtering. For example, the first electron transporting layer 131 is a ZnO film.

For example, the ITO substrate is ultrasonically cleaned with deionized water and isopropyl alcohol for 15 minutes, and then dried with nitrogen, and baked at 135° C. for 5 minutes. Next, the ITO substrate is treated with ultraviolet ozone for 10 minutes, so as to further clean organic pollutants attached to the surface of the ITO substrate, and passivate the surface defects of the ITO substrate.

Firstly, the cleaned ITO substrate is conveyed into a magnetron sputtering chamber, argon gas is introduced when the pressure of the chamber reaches 5×10⁻⁴ Pa, and the flow rate of the argon gas is 30 standard liters per minute (sccm) to 60 sccm, inclusive. For example, the flow rate of the argon gas may be 40 sccm to 50 sccm, inclusive. The pressure of the chamber is maintained to be in a range of 0.4 Pa to 1 Pa, inclusive. For example, the pressure of the chamber may be in a range of 0.5 Pa to 0.6 Pa, inclusive.

Power of a radio frequency source is set to be 20 W to 150 W, inclusive. For example, the power of the radio frequency source may be 50 W to 100 W, inclusive. After the radio frequency source is turned on for 5 minutes (i.e., starting for 5 minutes), a baffle is provided to enable the target material to be deposited on the ITO substrate. After the set process time is over, it is possible to stop performing the sputtering process, and taking the ITO substrate out of the processing cavity, so that a ZnO film may be deposited on the ITO substrate to serve as the first electron transporting layer 131.

In some other examples, the second electron transporting layer 132 may be formed by means of multi-target sputtering. For example, the second electron transporting layer 132 is a MgZnO film.

After the ITO substrate is cleaned, the cleaned ITO substrate is conveyed into a magnetron sputtering chamber, argon gas is introduced when the pressure of the chamber reaches 5×10⁻⁴ Pa, the flow rate of the argon gas is 30 sccm to 60 sccm, inclusive. For example, the flow rate of the argon gas may be 40 sccm to 50 sccm, inclusive. The pressure of the chamber is maintained to be in a range of 0.4 Pa to 1 Pa, inclusive. For example, the pressure of the chamber may be in a range of 0.5 Pa to 0.6 Pa, inclusive.

Power of a first radio frequency source is set to be 20 W to 150 W, inclusive. For example, the power of the first radio frequency source may be 50 W to 100 W, inclusive. Power of a second radio frequency source is set to be 20 W to 150 W, inclusive. For example, the power of the second radio frequency source may be 50 W to 100 W, inclusive.

After the first radio frequency source and the second radio frequency source are turned on for 5 minutes (i.e., starting for 5 minutes), target baffles of the first radio frequency source and the second radio frequency source are provided to enable the target materials are deposited on the ITO substrate. It will be understood that the first radio frequency source may be used to sputter ZnO, and the second radio frequency source may be used to sputter MgO, so that Mg and Zn ions may be deposited on the ITO substrate to form a MgZnO film.

After the set process time is over, it is possible to stop performing the sputtering process, and taking the ITO substrate out of the processing cavity, so that a MgZnO film may be deposited on the ITO substrate to serve as the second electron transporting layer 132. For example, the second electron transporting layer 132 may be deposited on a side of the first electron transporting layer 131 away from the second electrode 124.

It will be understood that the thickness of the film deposited on the ITO substrate may be controlled by controlling the time of the sputtering process, the pressure of the processing chamber, the power of the radio frequency source, and the like. For example, the longer the time the sputtering process, the thicker the film thickness. The higher the sputtering power, the stronger the argon (Ar) ion bombardment, the size of particles (e.g., ZnO nanoparticles or MgZnO nanoparticles) in the film increases, and the film deposition rate increases. The sputtering pressure is increased, the freedom of the atom is reduced, the Ar ion energy is weakened, and the bombardment is weakened, so that the crystallinity of the film is reduced, and the growth rate is reduced.

It will be understood that at least two electron transporting layers 130 that are stacked can be obtained by repeating the above steps.

It will be understood that, the at least two electron transporting layers 130 are formed by magnetron sputtering. In this way, the surface state of the oxide (e.g., ZnO) in the electron transporting layer 130 may be reduced, so as to reduce the interaction between the oxide in the electron transporting layer 130 and the quantum dot light-emitting layer 126, which is beneficial to reducing the non-radiative recombination (e.g., auger recombination) loss caused by the interface defect, and improving the luminous efficiency of the light-emitting device 110.

Furthermore, the influence of the electron transporting layer 130 formed later on the electron transporting layer 130 formed earlier may be reduced, and the electron transporting layer 130 formed earlier is not easily damaged, so that the thickness and the material of the at least two electron transporting layers 130 can be flexibly controlled. As a result, the optical properties and the electrical properties of the first light-emitting device 112 can be flexibly controlled, the consistency of the electron mobility and the hole mobility in the first light-emitting device 112 can be improved, the transmission capabilities of electrons and holes in the first light-emitting device 112 can be balanced, and the consistency of the number of electrons and the number of holes in the quantum dot light-emitting layer 126 can be improved, so that the luminous efficiency of the first light-emitting device 112 can be improved.

In addition, considering the first electron transporting layer 131 as a ZnO film as an example, the ZnO film formed by magnetron sputtering will have no or only a small amount of ZnO in the form of nanoparticles, so that the surface roughness of the ZnO film can be reduced. In some examples, as for the ZnO film formed by magnetron sputtering, the RMS surface roughness may be reduced to about 0.5 nm, so that the light emission performance of the light-emitting device 110 may be improved.

Moreover, the at least two electron transporting layers 130 formed by magnetron sputtering may be suitable for the high-resolution display, and the process is simple, which can be adapted to the manufacturing process of the driving backplate 150, thereby improving the display performance of the display panel 100, and reducing the production cost of the display panel 100.

The following will exemplify a method for manufacturing the light-emitting device 110 by considering the first light-emitting device 112 as an example.

It can be seen form the described above, the electron transporting layer 130 may be formed on the ITO substrate by magnetron sputtering.

For example, in a case where two electron transporting layers 130 (including the first electron transporting layer 131 and the second electron transporting layer 132) that are stacked are formed, the power of the first radio frequency source may be set to be 20 W to 150 W, inclusive; for example, the power of the first radio frequency source may be 50 W to 100 W, inclusive; the power of the second radio frequency source is set to be 20 W to 150 W, inclusive; for example, the power of the second radio frequency source may be 50 W to 100 W, inclusive.

After the first radio frequency source and the second radio frequency source are turned on for 5 minutes (i.e., starting for 5 minutes), a target baffle of the first radio frequency source is provided to enable the first electron transporting layer 131 is formed on the ITO substrate. For example, the first radio frequency source may be used to sputter ZnO. After 5 minutes to 15 minutes, a target baffle of the second radio frequency source is provided, and the first radio frequency source and the second radio frequency source co-sputter, so that the second electron transporting layer 132 is formed on a side of the first electron transporting layer 131 away from the ITO substrate (i.e., the second electrode 124).

It will be understood that the second radio frequency source may be used to sputter MgO, and the first radio frequency source and second radio frequency source are co-sputtered to enable the Mg and Zn ions to be deposited on the ITO substrate to form a MgZnO film. After 5 minutes to 15 minutes, it is possible to stop performing the sputtering process, and take the ITO substrate with at least two electron transporting layers 130 out of the processing cavity.

For example, after the first electron transporting layer 131 and the second electron transporting layer 132 are formed, a spin coating process, with a red CdSe-based quantum dot solution, is performed on a side of the second electron transporting layer 132 away from the first electron transporting layer 131. Then, a baking process is performed in a heating platform or an oven at the temperature of 80° C. to 150° C. for 5 minutes to 30 minutes. For example, it is possible to control the temperature of the heating platform to be 120° C., and the baking time may be 10 minutes, so as to form the quantum dot light-emitting layer 126 on the side of the at least two electron transporting layers 130 away from the second electrode 124.

The substrate with the film layers (the second electrode 124, the at least two electron transporting layers 130 and the quantum dot light-emitting layer 126) is placed in a thermal evaporator, and a hole transporting layer 146, and thermally evaporated under the vacuum degree of 5×10⁻⁴ Pa to 4×10⁻⁵ Pa to form a hole injection layer 144 and a first electrode 122.

In some examples, after the first electrode 122 is formed, a glass plate may be provided to cover the first electrode 122, and an encapsulation adhesive may be provided between the first electrode 122 and the glass plate. The encapsulation adhesive may be cured by means of ultraviolet irradiation, so as to protect the light-emitting device 110 (the first light-emitting device 112).

In some examples, as shown in FIGS. 3A to 3C, the plurality of light-emitting devices 110 further include a third light-emitting device 116. The third light-emitting device 116 is used to emit light of a third color. The wavelength of the light of the second color is greater than a wavelength of the light of the third color.

For example, the light of the third color is blue light (a wavelength of which is approximately 400 nm to 470 nm, inclusive).

It will be understood that the size of the quantum dot core of the quantum dot 1261 in the second light-emitting device 114 is greater than a size of a quantum dot core of a quantum dot 1261 in the third light-emitting device 116.

By adjusting the size of the quantum dot core in the quantum dot 1261 in different light-emitting devices 110 (the first light-emitting device 112, the second light-emitting device 114, and the third light-emitting device 116), the first light-emitting device 112, the second light-emitting device 114, and the third light-emitting device 116 may emit light of different colors, so that the display panel 100 may realize the full-color image display.

In some embodiments, the number of the electron transporting layers in the first light-emitting device 112 is less than the number of the electron transporting layers in the second light-emitting device 116.

It will be understood that the number of electrons transferred into the quantum dot light-emitting layer 126 may be adjusted by adjusting the number of the electron transporting layers 130.

Therefore, the number of the electron transporting layers 130 in the first light-emitting device 112 is set to be less than the number of the electron transporting layers 130 in the third light-emitting device 116. That is, it is possible to set the different numbers of electron transporting layers 130 in a targeted manner according to the color of the emitted light (wavelength of the emitted light) of the light-emitting device 110.

In this way, the number of electrons in the quantum dot light-emitting layer 126 in the light-emitting device 110 with a different color can be respectively adjusted, so as to improve the consistency between the number of electrons and the number of holes in the quantum dot light-emitting layer 126 in the light-emitting device 110 with a different color in a targeted manner, so that the luminous efficiency of the light-emitting device 110 with a different color can be improved in a targeted manner, and the service live of the light-emitting device 110 with a different color can be prolonged in a targeted manner.

It can be seen from the above, the number of electron transporting layers 130 in the first light-emitting device 112 is less than the number of electron transporting layers 130 in the second light-emitting device 114. In some examples, as shown in FIGS. 3A to 3C, the number of electron transporting layers 130 in the second light-emitting device 114 is equal to the number of electron transporting layers in the third light-emitting device 116.

It can be seen from the above, the second electrode 124 is close to the driving backplate 150 relative to the first electrode 122. In some examples, as shown in FIG. 5A, the third light-emitting device 116 includes a third first electrode 122c. For example, the first electrodes 122 of the plurality of light-emitting devices 110 (including the first light-emitting device 112, the second light-emitting device 116 and the third light-emitting device 116) constitute a whole-layer structure. The third first electrode 122c is a portion of the whole-layer structure of the first electrodes 122.

The distance d2 between the surface of the second first electrode 122b away from the driving backplate 150 and the driving backplate 150 is equal to or approximately equal to a distance d3 between a surface of the third first electrode 122c away from the driving backplate 150 and the driving backplate 150.

With this arrangement, the thicknesses of the first electrodes 122 (e.g., the first first electrode 122a and the second first electrode 122b) of different light-emitting devices 110 may be equal or approximately equal (that is, the whole-layer structure of the first electrodes 122 has a same or approximately same thickness at different positions), so that the consistency of the number of holes transmitted from the first electrode 122 to the quantum dot light-emitting layer 126 in different light-emitting devices 110 is improved, and the reliability of the plurality of light-emitting devices 110 is improved.

In some examples, as shown in FIG. 5B, the filling layer 128 is also located on a surface of the third first electrode 122c away from the driving backplate 150. The surface of the filling layer 128 away from the driving backplate 150 is flush or substantially flush with the surface of the first first electrode 122a away from the driving backplate 150, so that the structural regularity of the light-emitting devices 110 is improved.

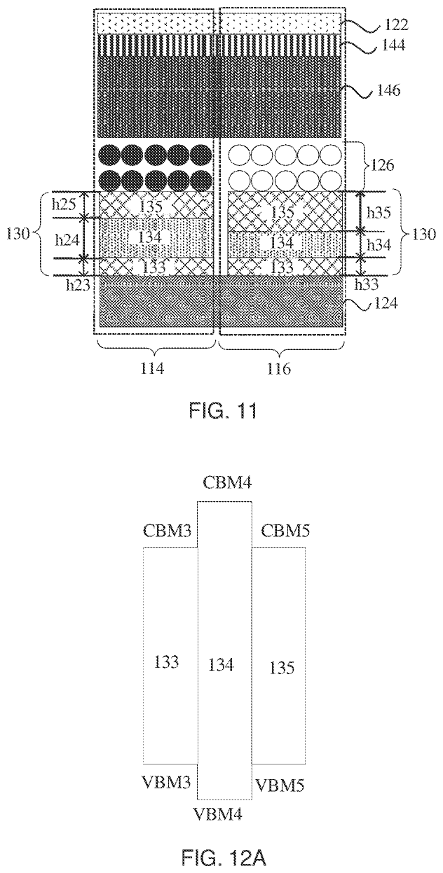

FIG. 11 is a diagram showing structures of a first light-emitting device and a second light-emitting device, in accordance with some embodiments.

In some embodiments, as shown in FIG. 11, at least two electron transporting layers 130 of at least one light-emitting device 110 of the second light-emitting device 114 and the third light-emitting device 116 include a third electron transporting layer 133, a fourth electron transporting layer 134, and a fifth electron transporting layer 135.

In some examples, as shown in FIG. 11, the second light-emitting device 114 and the third light-emitting device 116 each include a third electron transporting layer 133, a fourth electron transporting layer 134, and a fifth electron transporting layer 135.

In some examples, an electron mobility of the fourth electron transporting layer 134 is smaller than an electron mobility of the third electron transporting layer 133, and the electron mobility of the fourth electron transporting layer 134 is smaller than an electron mobility of the fifth electron transporting layer 135.

In this way, it is possible to reduce the electron mobility of the at least two electron transporting layers 130 as a whole, so that the number of electrons in the quantum dot light-emitting layer 126 is reduced, and the consistency of the number of electrons and the number of holes in the quantum dot light-emitting layer 126 is improved. As a result, the luminous efficiency of the light-emitting device 110 is improved.

In some examples, the electron mobility of the third electron transporting layer 133 is equal to or approximately equal to the electron mobility of the fifth electron transporting layer 135.

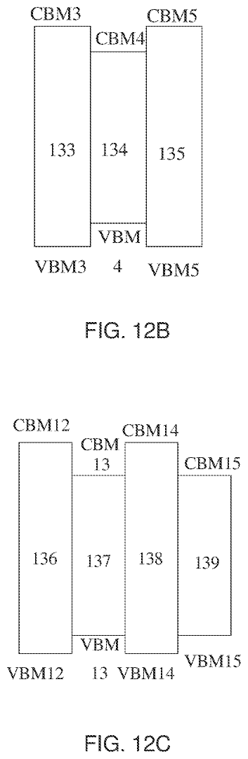

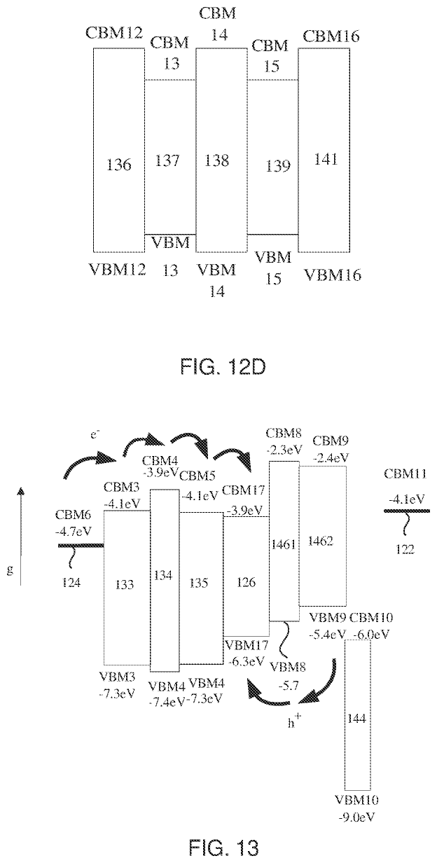

FIG. 12A is a diagram showing an energy level relationship of the third electron transporting layer, the fourth electron transporting layer and the fifth electron transporting layer, in accordance with some embodiments. FIG. 12B is a diagram showing an energy level relationship of the third electron transporting layer, the fourth electron transporting layer and the fifth electron transporting layer, in accordance with some other embodiments.

In some embodiments, as shown in FIG. 11, the third electron transporting layer 133, the fourth electron transporting layer 134, and the fifth electron transporting layer 135 are sequentially far away from the second electrode 124 in a direction from the second electrode 124 to the quantum dot light-emitting layer 126.

As shown in FIGS. 12A and 12B, an energy of a conduction band minimum CBM3 of the third electron transporting layer 133 is less than an energy of a conduction band minimum CBM4 of the fourth electron transporting layer 134. Alternatively, the energy of the conduction band minimum CBM4 of the fourth electron transporting layer 134 is less than an energy of a conduction band minimum CBM5 of the fifth electron transporting layer 135.

The third electron transporting layer 133, the fourth electron transporting layer 134, and the fifth electron transporting layer 135 are sequentially far away from the second electrode 124 in the direction from the second electrode 124 to the quantum dot light-emitting layer 126. Therefore, as shown in FIG. 12A, the energy of the conduction band minimum CBM3 of the third electron transporting layer 133 is set to be less than the energy of the conduction band minimum CBM4 of the fourth electron transporting layer 134, so that an electron transport barrier may be formed between the third electron transporting layer 133 and the fourth electron transporting layer 134.

Alternatively, as shown in FIG. 12B, the energy of the conduction band minimum CBM4 of the fourth electron transporting layer 134 is set to be less than the energy of the conduction band minimum CBM5 of the fifth electron transporting layer 135, so that an electron transport barrier may be formed between the fourth electron transporting layer 134 and the fifth electron transporting layer 135.

In this way, it is possible to block the transmission of electrons to the quantum dot light-emitting layer 126, reduce the number of electrons in the quantum dot light-emitting layer 126, and increase the consistency of the number of electrons and the number of holes in the quantum dot light-emitting layer 126, thereby improving the luminous efficiency of the light-emitting device 110.

In some examples, as shown in FIG. 12A, an energy of a valence band maximum VBM4 of the fourth electron transporting layer 134 is less than an energy of a valence band maximum VBM3 of the third electron transporting layer 133. The energy of the valence band maximum VBM4 of the fourth electron transporting layer 134 is less than an energy of a valence band maximum VBM5 of the fifth electron transporting layer 135.

In some other examples, as shown in FIG. 12B, the energy of the valence band maximum VBM4 of the fourth electron transporting layer 134 is greater than the energy of the valence band maximum VBM3 of the third electron transporting layer 133. The energy of the valence band maximum VBM4 of the fourth electron transporting layer 134 is greater than the energy of the valence band maximum VBM5 of the fifth electron transporting layer 135.

In some embodiments, as shown in FIGS. 12A and 12B, the energy of the conduction band minimum CBM3 of the third electron transporting layer 133 is equal to the energy of the conduction band minimum CBM5 of the fifth electron transporting layer 135.

In some examples, it is possible to set the materials of the third electron transporting layer 133 and the fifth electron transporting layer 135 to be the same to enable the energy of the conduction band minimum CBM3 of the third electron transporting layer 133 to equal to the energy of the conduction band minimum CBM5 of the fifth electron transporting layer 135, so that the ease of manufacturing the light-emitting devices 110 (e.g., the second light-emitting device 114 and the third light-emitting device 116) is improved.

In some examples, as shown in FIGS. 12A and 12B, the energy of the valence band maximum VBM3 of the third electron transporting layer 133 is equal to the energy of the valence band maximum VBM5 of the fifth electron transporting layer 135.

FIG. 12C is a diagram showing an energy level relationship of a sixth electron transporting layer, a seventh electron transporting layer, an eighth electron transporting layer and a ninth electron transporting layer, in accordance with some embodiments. FIG. 12D is a diagram showing an energy relationship of a sixth electron transporting layer, a seventh electron transporting layer, an eighth electron transporting layer, a ninth electron transporting layer and a tenth electron transporting layer, in accordance with some embodiments.

In some embodiments, as shown in FIG. 12C, any light-emitting device 110 (e.g., the first light-emitting device 112, the second light-emitting device 114 or the third light-emitting device 116) of the plurality of light-emitting devices 110 includes a sixth electron transporting layer 136, a seventh electron transporting layer 137, an eighth electron transporting layer 138, and a ninth electron transporting layer 139.

In some examples, the sixth electron transporting layer 136, the seventh electron transporting layer 137, the eighth electron transporting layer 138, and the ninth electron transporting layer 139 are sequentially far away from the second electrode 124 in a direction from the second electrode 124 to the quantum dot light-emitting layer 126.

In some examples, as shown in FIG. 12C, an energy of a conduction band minimum CBM12 of the sixth electron transporting layer 136 is greater than an energy of a conduction band minimum CBM13 of the seventh electron transporting layer 137. The energy of the conduction band minimum CBM13 of the seventh electron transporting layer 137 is less than an energy of a conduction band minimum CBM14 of the eighth electron transporting layer 138. The energy of the conduction band minimum CBM14 of the eighth electron transporting layer 138 is greater than an energy of a conduction band minimum CBM15 of the ninth electron transporting layer 139.

In this way, an electron transporting barrier may be formed between the sixth electron transporting layer 136, the seventh electron transporting layer 137, the eighth electron transporting layer 138, and the ninth electron transporting layer 139, which blocks the transmission of electrons to the quantum dot light-emitting layer 126, reduces the number of electrons in the quantum dot light-emitting layer 126, and increases the consistency of the number of electrons and the number of holes in the quantum dot light-emitting layer 126, thereby improving the luminous efficiency of the light-emitting device 110.

In some examples, as shown in FIG. 12C, an energy of a valence band maximum VBM12 of the sixth electron transporting layer 136 is less than an energy of a valence band maximum VBM13 of the seventh electron transporting layer 137. The energy of the valence band maximum VBM13 of the seventh electron transporting layer 137 is greater than an energy of a valence band maximum VBM14 of the eighth electron transporting layer 138. The energy of the valence band maximum VBM14 of the eighth electron transporting layer 138 is less than an energy of a valence band maximum VBM15 of the ninth electron transporting layer 139.

In some other examples, as shown in FIG. 12D, any light-emitting device 110 (e.g., the first light-emitting device 112, the second light-emitting device 114, or the third light-emitting device 116) of the plurality of light-emitting devices 110 includes a sixth electron transporting layer 136, a seventh electron transporting layer 137, an eighth electron transporting layer 138, a ninth electron transporting layer 139 and a tenth electron transporting layer 141.

In some examples, the sixth electron transporting layer 136, the seventh electron transporting layer 137, the eighth electron transporting layer 138, the ninth electron transporting layer 139, and the tenth electron transporting layer 141 are sequentially far away from the second electrode 124 in a direction from the second electrode 124 to the quantum dot light-emitting layer 126.

In some examples, as shown in FIG. 12D, an energy of a conduction band minimum CBM12 of the sixth electron transporting layer 136 is greater than an energy of a conduction band minimum CBM13 of the seventh electron transporting layer 137. The energy of the conduction band minimum CBM13 of the seventh electron transporting layer 137 is less than an energy of a conduction band minimum CBM14 of the eighth electron transporting layer 138. The energy of the conduction band minimum CBM14 of the eighth electron transporting layer 138 is greater than an energy of a conduction band minimum CBM15 of the ninth electron transporting layer 139. The energy of the conduction band minimum CBM15 of the ninth electron transporting layer 139 is less than an energy of a conduction band minimum CBM16 of the tenth electron transporting layer 141.

In this way, an electron transporting barrier may be formed between the sixth electron transporting layer 136, the seventh electron transporting layer 137, the eighth electron transporting layer 138, the ninth electron transporting layer 139, and the tenth electron transporting layer 141, which blocks the transmission of electrons to the quantum dot light-emitting layer 126, reduces the number of electrons in the quantum dot light-emitting layer 126, and increases the consistency of the number of electrons and the number of holes in the quantum dot light-emitting layer 126, thereby improving the luminous efficiency of the light-emitting device 110.

In some examples, as shown in FIG. 12D, an energy of a valence band maximum VBM12 of the sixth electron transporting layer 136 is less than an energy of a valence band maximum VBM13 of the seventh electron transporting layer 137. The energy of the valence band maximum VBM13 of the seventh electron transporting layer 137 is greater than an energy of a valence band maximum VBM14 of the eighth electron transporting layer 138. The energy of the valence band maximum VBM14 of the eighth electron transporting layer 138 is less than an energy of a valence band maximum VBM15 of the ninth electron transporting layer 139. The energy of the valence band maximum VBM15 of the ninth electron transporting layer 139 is greater than an energy of a valence band maximum VBM16 of the tenth electron transporting layer 141.

It can be seen from the above, in some examples, the at least two electron transporting layers 130 may be formed by magnetron sputtering. The method of manufacturing the third electron transporting layer 133, the fourth electron transporting layer 134, and the fifth electron transporting layer 135 will be illustrated below.

In some examples, in a case where three electron transporting layers 130 (including the third electron transporting layer 133, the fourth electron transporting layer 134, and the fifth electron transporting layer 135) that are stacked are formed, power of a first radio frequency source may be set to be 20 W to 150 W, inclusive; for example, the power of the first radio frequency source may be 50 W to 100 W, inclusive; power of a second radio frequency source may be set to be 20 W to 150 W, inclusive; for example, the power of the second radio frequency source may be 50 W to 100 W, inclusive.

After the first radio frequency source and the second radio frequency source are turned on for 5 minutes (i.e., starting for 5 minutes), a target baffle of the first radio frequency source is provided to enable the third electron transporting layer 133 is formed on the ITO substrate. For example, the first radio frequency source may be used to sputter ZnO, and the third electron transporting layer 133 is a ZnO film. After 5 minutes to 15 minutes, a target baffle of the second radio frequency source is provided, and the first radio frequency source and the second radio frequency source co-sputter, so that the fourth electron transporting layer 134 is formed on the side of the third electron transporting layer 133 away from the ITO substrate (i.e., the second electrode 124). It will be understood that the second radio frequency source may be used to sputter MgO, and the first radio frequency source and second radio frequency source are co-sputtered to enable the Mg and Zn ions to be deposited on the ITO substrate to form a MgZnO film.

It will be understood that, a content ratio of different elements in the fourth electron transporting layer 134 may be controlled by adjusting the power of the first radio frequency source and the power of the second radio frequency source to meet different requirements.

After 5 minutes to 15 minutes, the second radio frequency source is turned off, and the first radio frequency source continues sputtering to form a fifth electron transporting layer 135 on a side of the fourth electron transporting layer 134 away from the third electron transporting layer 133. The fifth electron transporting layer 135 is a ZnO film. Then, after 5 minutes to 15 minutes, it is possible to stop performing the sputtering process, and take the ITO substrate with at least two electron transporting layers 130 out of the processing cavity.

In some other examples, in a case where three electron transporting layers 130 (including the third electron transporting layer 133, the fourth electron transporting layer 134, and the fifth electron transporting layer 135) that are stacked are formed, power of a first radio frequency source may be set to be 20 W to 150 W, inclusive; for example, the power of the first radio frequency source may be 50 W to 100 W, inclusive; power of a second radio frequency source is set to be 20 W to 150 W, inclusive; for example, the power of the second radio frequency source may be 50 W to 100 W, inclusive.

After the first radio frequency source and the second radio frequency source are turned on for 5 minutes (i.e., starting for 5 minutes), a target baffle of the first radio frequency source is provided to enable the third electron transporting layer 133 to be deposited on the ITO substrate. For example, the first radio frequency source may be used to sputter ZnO, and the third electron transporting layer 133 is a ZnO film.

After 5 minutes to 15 minutes, the first radio frequency source is turned off, a target baffle of the second radio frequency source is provided to enable the fourth electron transporting layer 134 to be deposited on a side of the third electron transporting layer 133 away from the ITO substrate (i.e., the second electrode 124). It will be understood that a second radio frequency source may be used to sputter MgZnO, and the fourth electron transporting layer 134 is a MgZnO film.

After 5 minutes to 15 minutes, the second radio frequency source is turned off, and the first radio frequency source is turned on to continue sputtering to form a fifth electron transporting layer 135 on a side of the fourth electron transporting layer 134 away from the third electron transporting layer 133. The fifth electron transporting layer 135 is a ZnO film. Then, after 5 minutes to 15 minutes, it is possible to stop performing the sputtering process, and take the ITO substrate with at least two electron transporting layers 130 out of the processing cavity.

For example, four, five, six, or more than two electron transporting layers 130 that are stacked may be formed in the manner described above.

FIG. 13 is a diagram showing an energy level structure of a light-emitting device, in accordance with some other embodiments.

In some examples, as shown in FIG. 13, a direction represented by the arrow g is a direction in which the energy (including the energy of the valence band maximum VBM and the energy of the conduction band minimum CBM) increases. The arrow e⁻ represents the migration path of electrons, and the arrow h⁺ represents the migration path of holes.

Considering the second light-emitting device 114 as an example, of the second electrode 124 of the second light-emitting device 114, the material is ITO, and the energy of the conduction band minimum CBM6 is −4.7 eV.

The third electron transporting layer 133 is a ZnO film, and of the third electron transporting layer 133, the energy of the conduction band minimum CBM3 is −4.1 eV, and the energy of the valence band maximum VBM3 is-7.3 eV.

The fourth electron transporting layer 134 is a ZnMgO film, and of the fourth electron transporting layer 134, the energy of the conduction band minimum CBM4 is −3.9 eV, and the energy of the valence band maximum VBM4 is −7.4 eV.

The fifth electron transporting layer 135 is a ZnO film, and of the fifth electron transporting layer 135, the energy of the conduction band minimum CBM5 is −4.1 eV, and the energy of the valence band maximum VBM5 is-7.3 eV.

Of the green quantum dot (GQD) light-emitting layer, a material is CdSe-based quantum dot material, and an energy of a conduction minimum CBM17 is −3.9 eV, and an energy of a valence band maximum VBM17 is −6.3 eV.

A first hole transporting layer 1461 is a TCTA film, and of the first hole transporting layer 1461, an energy of a conduction band minimum CBM8 is −2.3 eV, and an energy of a valence band maximum VBM8 is −5.7 eV.

A second hole transporting layer 1462 is an NPB film, and of the second hole transporting layer 1462, an energy of a conduction band minimum CBM9 is −2.4 eV, and an energy of a valence band maximum VBM9 is −5.4 eV.

A hole injection layer 144 is a MoO₃ film, and of the hole injection layer 144, an energy of a conduction band minimum CBM10 is −6.0 eV, and an energy of a valence band maximum VBM10 is −9.0 eV.

Of the first electrode 122, a material includes Mg and Ag (the mass ratio of Mg to Ag is 2:8), and an energy of a conduction band minimum CBM11 is −4.1 eV.

In some embodiments, a material of the third electron transporting layer 133 includes any one of ZnO, GZO, AZO, IZO, IGZO, and ZnMgO. A material of the fourth electron transporting layer 134 includes any one of ZnO, GZO, AZO, IZO, IGZO, and ZnMgO. A material of the fifth electron transporting layer 135 includes any one of ZnO, GZO, AZO, IZO, IGZO, and ZnMgO. The material of the fourth electron transporting layer 134 is different from the material of the third electron transporting layer 133; and/or the material of the fourth electron transporting layer 134 is different from the material of the fifth electron transporting layer 135.

In this way, the electron mobility of the fourth electron transporting layer 134 is smaller than the electron mobility of the third electron transporting layer 133, and the electron mobility of the fourth electron transporting layer 134 is smaller than the electron mobility of the fifth electron transporting layer 135.

In addition, an electron transporting barrier may be formed between the third electron transporting layer 133, the fourth electron transporting layer 134 and the fifth electron transporting layer 135, which blocks the transmission of electrons to the quantum dot light-emitting layer 126, and increases the consistency of the number of electrons and the number of holes in the quantum dot light-emitting layer 126, thereby improving the luminous efficiency of the light-emitting device 110.

In some examples, in a case where the third electron transporting layer 133, the fourth electron transporting layer 134, and the fifth electron transporting layer 135 are sequentially far away from the second electrode 124 in a direction from the second electrode 124 to the quantum dot light-emitting layer 126, the material of the third electron transporting layer 133 includes ZnO, the material of the fourth electron transporting layer 134 includes ZnMgO, and the material of the fifth electron transporting layer 135 includes ZnO.

It will be understood that the third electron transporting layer 133, the fourth electron transporting layer 134, and the fifth electron transporting layer 135 may each be other n-type oxide films.

It can be seen from the above, the thickness of each electron transporting layer 130 of the at least two electron transporting layers 130 may affect the number of electrons in the quantum dot light-emitting layer 126.

In some embodiments, as shown in FIG. 11, in the case where the second light-emitting device 114 includes the third electron transporting layer 133, the fourth electron transporting layer 134, and the fifth electron transporting layer 135, a thickness h23 of the third electron transporting layer 133 is greater than 0 nm and less than or equal to 40 nm; a thickness h24 of the fourth electron transporting layer 134 is greater than 0 nm and less than or equal to 30 nm; a thickness h25 of the fifth electron transporting layer 135 is greater than 0 nm and less than or equal to 40 nm.

It will be understood that, in the second light-emitting device 114, the thickness h23 of the third electron transit layer 133, the thickness h24 of the fourth electron transit layer 134, and the thickness h25 of the fifth electron transit layer 135 may be the same or different.

In some examples, the thickness h23 of the third electron transporting layer 133 is greater than 0 nm and less than or equal to 35 nm. In some other examples, the thickness h23 of the third electron transporting layer 133 is greater than 0 nm and less than or equal to 30 nm. In yet some other examples, the thickness h23 of the third electron transporting layer 133 is greater than 0 nm and less than or equal to 25 nm.

For example, the thickness h23 of the third electron transporting layer 133 may be 15 nm, 20 nm, 25 nm, 35 nm, or the like.

In some examples, the thickness h24 of the fourth electron transporting layer 134 is greater than 0 nm and less than or equal to 25 nm. In some other examples, the thickness h24 of the fourth electron transporting layer 134 is greater than 0 nm and less than or equal to 20 nm. In yet some other examples, the thickness h24 of the fourth electron transporting layer 134 is greater than 0 nm and less than or equal to 15 nm.

For example, the thickness h24 of the fourth electron transporting layer 134 may be 15 nm, 20 nm, 25 nm, 28 nm, or the like.

In some examples, the thickness h25 of the fifth electron transporting layer 135 is greater than 0 nm and less than or equal to 35 nm. In some other examples, the thickness h25 of the fifth electron transporting layer 135 is greater than 0 nm and less than or equal to 30 nm. In yet some other examples, the thickness h25 of the fifth electron transporting layer 135 is greater than 0 nm and less than or equal to 25 nm.

For example, the thickness h25 of the fifth electron transporting layer 135 may be 15 nm, 20 nm, 25 nm, 35 nm, or the like.

It will be understood that, in the second light-emitting device 114, the thickness h23 of the third electron transporting layer 133 is greater than 0 nm and less than or equal to 40 nm, the thickness h24 of the fourth electron transporting layer 134 is greater than 0 nm and less than or equal to 30 nm, and the thickness h25 of the fifth electron transporting layer 135 is greater than 0 nm and less than or equal to 40 nm, so that it is possible to prevent the performance of the second light-emitting device 114 form being affected caused by a fact, due to the excessive thickness of the third electron transporting layer 133, the fourth electron transporting layer 134 or the fifth electron transporting layer 135 (for example, the thickness h23 of the third electron transporting layer 133 is greater than 40 nm, the thickness h24 of the fourth electron transporting layer 134 is greater than 30 nm, or the thickness h25 of the fifth electron transporting layer 135 is greater than 40 nm), that the turn-on voltage of the second light-emitting device 114 from being increased, the current from being reduced and the luminance from being reduced.

Moreover, the thickness of the third electron transporting layer 133, the fourth electron transporting layer 134, or the fifth electron transporting layer 135 is prevented from being too large (for example, the thickness h23 of the third electron transporting layer 133 is greater than 40 nm, the thickness h24 of the fourth electron transporting layer 134 is greater than 30 nm, or the thickness h25 of the fifth electron transporting layer 135 is greater than 40 nm), so that it is possible to increase the luminous intensity of the second light-emitting device 114 at the front (away from the driving backplate 150) to enable the light emitted by the second light-emitting device 114 to meet lambertian distribution approximately, and reduce the luminous intensity of the second light-emitting device 114 at the side. As a result, the light extraction efficiency of the second light-emitting device 114 is improved, and the luminance of the second light-emitting device 114 is increased, so that the power consumption of the display panel 100 is reduced.

In some embodiments, in a case where the third light-emitting device 116 includes a third electron transporting layer 133, a fourth electron transporting layer 134, and a fifth electron transporting layer 135, a thickness of the third electron transporting layer 133 is greater than 0 nm and less than or equal to 30 nm; a thickness of the fourth electron transporting layer 134 is greater than 0 nm and less than or equal to 20 nm; a thickness of the fifth electron transit layer 135 is greater than 0 nm and less than or equal to 30 nm.

It will be understood that, in the third light-emitting device 116, the thickness h33 of the third electron transit layer 133, the thickness h34 of the fourth electron transit layer 134, and the thickness h35 of the fifth electron transit layer 135 may be the same or different.

In some examples, the thickness h33 of the third electron transporting layer 133 is greater than 0 nm and less than or equal to 25 nm. In some other examples, the thickness h33 of the third electron transporting layer 133 is greater than 0 nm and less than or equal to 20 nm. In yet some other examples, the thickness h33 of the third electron transporting layer 133 is greater than 0 nm and less than or equal to 15 nm.

For example, the thickness h33 of the third electron transporting layer 133 may be 15 nm, 20 nm, 25 nm, 28 nm, or the like.

In some examples, the thickness h34 of the fourth electron transporting layer 134 is greater than 0 nm and less than or equal to 15 nm. In some other examples, the thickness h34 of the fourth electron transporting layer 134 is greater than 0 nm and less than or equal to 10 nm. In yet some other examples, the thickness h34 of the fourth electron transporting layer 134 is greater than 0 nm and less than or equal to 5 nm.

For example, the thickness h34 of the fourth electron transporting layer 134 may be 10 nm, 12 nm, 15 nm, 18 nm, or the like.

In some examples, the thickness h35 of the fifth electron transporting layer 135 is greater than 0 nm and less than or equal to 25 nm. In some other examples, the thickness h35 of the fifth electron transporting layer 135 is greater than 0 nm and less than or equal to 20 nm. In yet some other examples, the thickness h35 of the fifth electron transporting layer 135 is greater than 0 nm and less than or equal to 15 nm.

For example, the thickness h35 of the fifth electron transporting layer 135 may be 15 nm, 20 nm, 25 nm, 28 nm, or the like.

It will be understood that, in the third light-emitting device 116, the thickness h33 of the third electron transporting layer 133 is greater than 0 nm and less than or equal to 30 nm, the thickness h34 of the fourth electron transporting layer 134 is greater than 0 nm and less than or equal to 20 nm, and the thickness h35 of the fifth electron transporting layer 135 is greater than 0 nm and less than or equal to 30 nm, so that it is possible to prevent the performance of the third light-emitting device 116 form being affected caused by a fact, due to the excessive thickness of the third electron transporting layer 133, the fourth electron transporting layer 134 or the fifth electron transporting layer 135 (for example, the thickness h33 of the third electron transporting layer 133 is greater than 30 nm, the thickness h34 of the fourth electron transporting layer 134 is greater than 20 nm, or the thickness h35 of the fifth electron transporting layer 135 is greater than 30 nm), that the turn-on voltage of the third light-emitting device 116 from being increased, the current from being reduced and the luminance from being reduced.

Moreover, the thickness of the third electron transporting layer 133, the fourth electron transporting layer 134, or the fifth electron transporting layer 135 is prevented from being too large (for example, the thickness h33 of the third electron transporting layer 133 is greater than 30 nm, the thickness h34 of the fourth electron transporting layer 134 is greater than 20 nm, or the thickness h35 of the fifth electron transporting layer 135 is greater than 30 nm), so that it is possible to increase the luminous intensity of the third light-emitting device 116 at the front (away from the driving backplate 150) to enable the light emitted by the third light-emitting device 116 to meet lambertian distribution approximately, and reduce the luminous intensity of the third light-emitting device 116 at the side. As a result, the light extraction efficiency of the third light-emitting device 116 is improved, and the luminance of the third light-emitting device 116 is increased, so that the power consumption of the display panel 100 is reduced.

In some embodiments, in a case where the second light-emitting device 114 includes the third electron transporting layer 133, the fourth electron transporting layer 134, and the fifth electron transporting layer 135, the thickness h23 of the third electron transporting layer 133 is in a range of 5 nm to 20 nm, inclusive, the thickness h24 of the fourth electron transporting layer 134 is in a range of 1 nm to 15 nm, inclusive, and the thickness h25 of the fifth electron transporting layer 135 is in a range of 5 nm to 20 nm, inclusive.

In some examples, the thickness h23 of the third electron transporting layer 133 is in a range of 8 nm to 18 nm, inclusive, or a range of 5 nm to 15 nm, inclusive. For example, the thickness h23 of the third electron transporting layer 133 may be 6 nm, 10 nm, 15 nm, 18 nm, or the like.

In some examples, the thickness h24 of the fourth electron transporting layer 134 is in a range of 1 nm to 12 nm, inclusive, or a range of 1 nm to 10 nm, inclusive. For example, the thickness h23 of the third electron transporting layer 133 may be 3 nm, 8 nm, 12 nm, or the like.

In some examples, the thickness h25 of the fifth electron transporting layer 135 is in a range of 8 nm to 18 nm, inclusive, or a range of 5 nm to 15 nm, inclusive. For example, the thickness h25 of the fifth electron transporting layer 135 may be in a range of 6 nm, 10 nm, 15 nm, 18 nm, or the like.

It will be understood that, in the second light-emitting device 114, the thickness h23 of the third electron transporting layer 133 is set to be in the range of 5 nm to 20 nm, inclusive, the thickness h24 of the fourth electron transporting layer 134 is set to be in the range of 1 nm to 15 nm, inclusive, and the thickness h25 of the fifth electron transporting layer 135 is set to be in the range of 5 nm to 20 nm, inclusive, so that it is possible to prevent the current efficiency from being reduced caused by an overlarge current of the second light-emitting device 114 due to a fact that the thickness h23 of the third electron transporting layer 133, the thickness h24 of the fourth electron transporting layer 134, or the thickness h25 of the fifth electron transporting layer 135 is too small (for example, the thickness h23 of the third electron transporting layer 133 is less than 5 nm, the thickness h24 of the fourth electron transporting layer 134 is less than 1 nm, or the thickness h25 of the fifth electron transporting layer 135 is less than 5 nm).

Moreover, it is possible to prevent the performance of the second light-emitting device 114 form being affected caused by a fact, due to the excessive thickness h23 of the third electron transporting layer 133, the excessive thickness h24 of the fourth electron transporting layer 134, and the excessive thickness h25 of the fifth electron transporting layer 135 (for example, the thickness h23 of the third electron transporting layer 133 is greater than 20 nm, the thickness h24 of the fourth electron transporting layer 134 is greater than 15 nm, or the thickness h25 of the fifth electron transporting layer 135 is greater than 20 nm), that the turn-on voltage of the first light-emitting device 112 from being increased, the current from being reduced and the luminance from being reduced.

In addition, the thickness of the third electron transporting layer 133, the fourth electron transporting layer 134, or the fifth electron transporting layer 135 is prevented from being too large (for example, the thickness h23 of the third electron transporting layer 133 is greater than 20 nm, the thickness h24 of the fourth electron transporting layer 134 is greater than 15 nm, or the thickness h25 of the fifth electron transporting layer 135 is greater than 20 nm), so that it is possible to increase the luminous intensity of the second light-emitting device 114 at the front (away from the driving backplate 150), and reduce the luminous intensity of the second light-emitting device 114 at the side. As a result, the light extraction efficiency of the second light-emitting device 114 is improved, and the luminance of the second light-emitting device 114 is increased, so that the power consumption of the display panel 100 is reduced.

In some embodiments, in a case where the third light-emitting device 116 includes a third electron transporting layer 133, a fourth electron transporting layer 134, and a fifth electron transporting layer 135, a thickness h33 of the third electron transporting layer 133 is in a range of 5 nm to 15 nm, inclusive, a thickness h34 of the fourth electron transporting layer 134 is in a range of 1 nm to 15 nm, inclusive, and a thickness h35 of the fifth electron transporting layer 135 is in a range of 5 nm to 15 nm, inclusive.

In some examples, the thickness h33 of the third electron transporting layer 133 is in a range of 6 nm to 13 nm, inclusive, or a range of 8 nm to 10 nm, inclusive. For example, the thickness h33 of the third electron transporting layer 133 may be 6 nm, 8 nm, 9 nm, 12 nm, or the like.

In some examples, the thickness h34 of the fourth electron transporting layer 134 is in a range of 1 nm to 10 nm, inclusive, or a range of 1 nm to 5 nm, inclusive. For example, the thickness h34 of the fourth electron transporting layer 134 may be 3 nm, 8 nm, 10 nm, 12 nm, or the like.

In some examples, the thickness h35 of the fifth electron transporting layer 135 is in a range of 6 nm to 13 nm, inclusive, or a range of 8 nm to 10 nm, inclusive. For example, the thickness h35 of the fifth electron transporting layer 135 may be 6 nm, 8 nm, 9 nm, 12 nm, or the like.

It will be understood that, in the third light-emitting device 116, the thickness h33 of the third electron transporting layer 133 is set to be in the range of 5 nm to 15 nm, inclusive, the thickness h34 of the fourth electron transporting layer 134 is set to be in the range of 1 nm to 15 nm, inclusive, and the thickness h35 of the fifth electron transporting layer 135 is set to be in the range of 5 nm to 15 nm, inclusive, so that it is possible to prevent the current efficiency from being reduced caused by an overlarge current of the third light-emitting device 116 due to a fact that the thickness h33 of the third electron transporting layer 133, the thickness h34 of the fourth electron transporting layer 134, or the thickness h35 of the fifth electron transporting layer 135 is too small (for example, the thickness h33 of the third electron transporting layer 133 is less than 5 nm, the thickness h34 of the fourth electron transporting layer 134 is less than 1 nm, or the thickness h35 of the fifth electron transporting layer 135 is less than 5 nm).

Moreover, it is possible to prevent the performance of the third light-emitting device 116 form being affected caused by a fact, due to the excessive thickness h33 of the third electron transporting layer 133, the excessive thickness h34 of the fourth electron transporting layer 134, and the excessive thickness h35 of the fifth electron transporting layer 135 (for example, the thickness h33 of the third electron transporting layer 133 is greater than 15 nm, the thickness h34 of the fourth electron transporting layer 134 is greater than 15 nm, or the thickness h35 of the fifth electron transporting layer 135 is greater than 15 nm), that the turn-on voltage of the third light-emitting device 116 from being increased, the current from being reduced and the luminance from being reduced.

In addition, the thickness h33 of the third electron transporting layer 133, the thickness h34 of the fourth electron transporting layer 134, or the thickness h35 of the fifth electron transporting layer 135 is prevented from being too large (for example, the thickness h33 of the third electron transporting layer 133 is greater than 15 nm, the thickness h34 of the fourth electron transporting layer 134 is greater than 15 nm, or the thickness h35 of the fifth electron transporting layer 135 is greater than 15 nm), so that it is possible to increase the luminous intensity of the third light-emitting device 116 at the front (away from the driving backplate 150), and reduce the luminous intensity of the third light-emitting device 116 at the side. As a result, the light extraction efficiency of the third light-emitting device 116 is improved, and the luminance of the third light-emitting device 116 is increased, so that the power consumption of the display panel 100 is reduced.

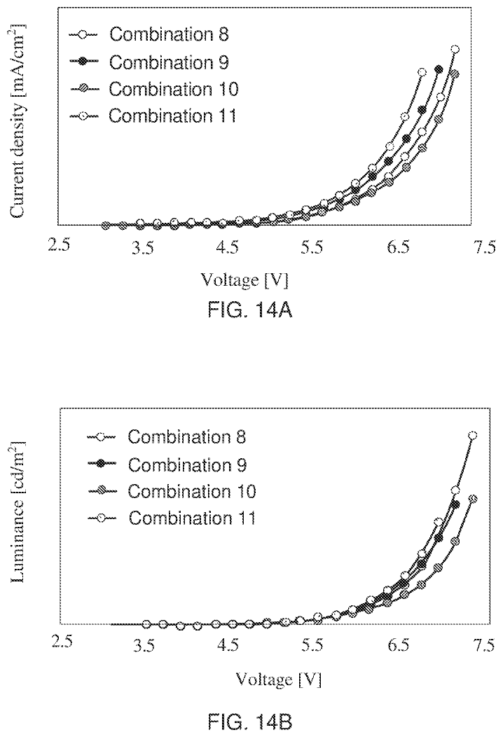

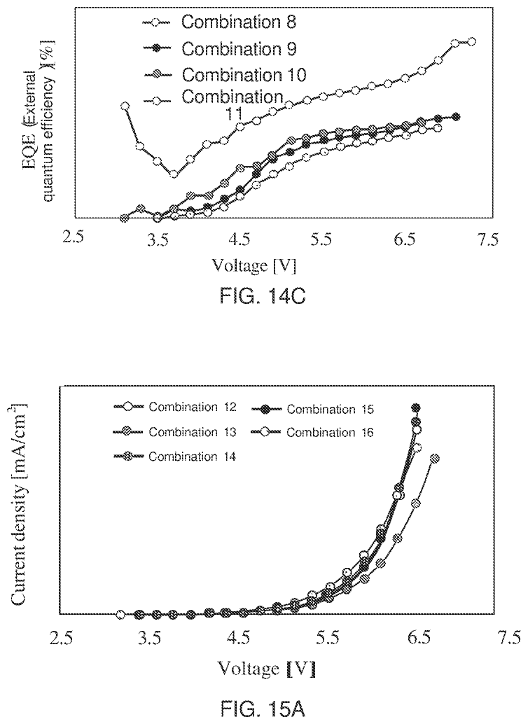

FIG. 14A is curve graph showing a variation of a current density with a voltage, in accordance with yet some other embodiments. FIG. 14B is a curve graph showing a variation of a luminance with a voltage, in accordance with some embodiments. FIG. 14C is a curve graph showing a variation of an external quantum efficiency with a voltage, in accordance with yet some other embodiments.

Hereinafter, referring to FIGS. 14A to 14C, in some embodiments of the present disclosure, the current density, the luminance, and the external quantum efficiency of the second light-emitting device 114 are illustrated in a case where the third electron transporting layer 133, the fourth electron transporting layer 134, and the fifth electron transporting layer 135 in the second light-emitting device 114 have different thicknesses.

Hereinafter, referring to FIGS. 14A to 14C, in some embodiments of the present disclosure, the current density, the luminance, and the external quantum efficiency of the second light-emitting device 114 are illustrated in a case where the third electron transporting layer 133, the fourth electron transporting layer 134, and the fifth electron transporting layer 135 in the second light-emitting device 114 have different thicknesses.

It will be understood that in FIG. 14A, the abscissa represents voltage in V, and the ordinate represents current density in mA/cm²; in FIG. 14B, the abscissa is voltage in V, and the ordinate is luminance in candela per square meter (cd/m²); in FIG. 14C, the abscissa represents voltage in V, and the ordinate represents the external quantum efficiency (EQE). It will be understood that, EQE is equal to the number of the emitted photons divide by the number of the injected holes. The greater the EQE, the better the light emission performance of the light-emitting device 110.

As shown in FIGS. 14A to 14C, Combinations 8 to 11 are combinations of electron transporting layers 130 of different thicknesses and materials.

In Combination 8, the third electron transporting layer 133 is a ZnO film with a thickness of 10.5 nm; the fourth electron transporting layer 134 is a ZnMgO film with a thickness of 9 nm; and the fifth electron transporting layer 135 is a ZnO film with a thickness of 10.5 nm. In the fourth electron transporting layer 134, the molar percentage of Mg in ZnMgO is 8%.

In Combination 9, the third electron transporting layer 133 is a ZnO film with a thickness of 21 nm; and the fourth electron transporting layer 134 is a ZnMgO film with a thickness of 9 nm. Combination 9 does not include a fifth electron transporting layer 135. In the fourth electron transporting layer 134, the molar percentage of Mg in ZnMgO is 8%.

In Combination 10, the third electron transporting layer 133 is a ZnMgO film with a thickness of 9 nm; and the fourth electron transporting layer 134 is a ZnO film with a thickness of 21 nm. Combination 10 also does not include a fifth electron transporting layer 135. In the fourth electron transporting layer 134, the molar percentage of Mg in ZnMgO is 8%.

In Combination 11, materials of the third electron transporting layer 133, the fourth electron transporting layer 134, and the fifth electron transporting layer 135 are all ZnO. That is, in this case, the at least two electron transporting layers 130 may be regarded as one electron transporting layer 130, which has a thickness of 30 nm.

As shown in FIGS. 14A and 14B, in a case where the voltage is increased, the luminance of the second light-emitting devices 114 respectively including Combination 9, Combination 10, and Combination 11 is increased, and the current density is also increased, so that the current efficiency is decreased. As shown in FIG. 14C, EQE of the second light-emitting device 114 is small in a case where Combination 9, Combination 10, or Combination 11 is included.

As shown in FIG. 14C, in a case where the voltage is increased, the second light-emitting device 114 including Combination 8 (i.e., the third electron transporting layer 133 is made of ZnO and has a thickness of 10.5 nm, the fourth electron transporting layer 134 is made of ZnMgO and has a thickness of 9 nm, and the fifth electron transporting layer 135 is made of ZnO, and has a thickness of 10.5 nm, and the mole percentage of Mg in ZnMgO is 8%) has the highest EQE, and the highest current efficiency, so that the light emission performance of the second light-emitting device 114 is improved.

That is, as shown in FIGS. 14A to 14C, the current density, the luminance, and the EQE of the second light-emitting device 114 in which three electron transporting layers 130 (Combination 8) are included are all better than those of the second light-emitting device 114 in which a single electron transporting layer 130 (Combination 11) is included and those of the second light-emitting device 114 in which two electron transporting layers 130 (Combination 9 or Combination 10) are included. That is, in a case where three electron transporting layers 130 are included, the second light-emitting device 114 may have a good light emission performance.

It will be understood that, in a case where three electron transporting layers 130 (Combination 8) are included, and the fourth electron transporting layer 134 is made of ZnMgO, it is possible to block electrons and reduce electron mobility by doping with Mg ions, so that the number of electrons in the quantum dot light-emitting layer 126 is reduced, and the luminous efficiency of the second light-emitting device 114 is improved.

In addition, in a case where the third electron transporting layer 133 is made of ZnO, the fourth electron transporting layer 134 is made of ZnMgO, and the fifth electron transporting layer 135 is made of ZnO, an energy difference may be generated between the third electron transporting layer 133, the fourth electron transporting layer 134, and the fifth electron transporting layer 135, so as to form an electron transport barrier, so that it is possible to block the transmission of electrons to the quantum dot light-emitting layer 126, and balance the transmission capabilities of electrons and the holes in the second light-emitting device 114.

Therefore, in some embodiments, in a case where the second light-emitting device 114 includes the third electron transporting layer 133, the fourth electron transporting layer 134, and the fifth electron transporting layer 135, the thickness h23 of the third electron transporting layer 133 is approximately 10.5 nm, the thickness h24 of the fourth electron transporting layer 134 is approximately 9 nm, and the thickness h25 of the fifth electron transporting layer 135 is approximately 10.5 nm.

It can be seen form the above, with this configuration, the current efficiency and the external quantum efficiency of the second light-emitting device 114 may be improved, so that the light emission performance of the first light-emitting device 114 may be improved.

It can be seen from the above, the material of the fourth electron transporting layer 134 includes ZnMgO. In some examples, in the fourth electron transporting layer 134, the molar percentage of Mg is greater than 0 and less than or equal to 50%; the sum of the molar percentage of Mg and the molar percentage of Zn is 1.

It will be understood, the material of the fourth electron transporting layer 134 includes Zn_{1-X}Mg_{X}O, where X is the molar percentage of Mg, and 1-X is the molar percentage of Zn.

It will be understood that, by adjusting the molar percentage of Mg in the fourth electron transporting layer 134, the electron mobility of the fourth electron transporting layer 134 and the energy (for example, the energy of the valence band maximum VBM and the energy of the conduction band minimum CBM) of the fourth electron transporting layer 134 may be adjusted, so that the number of electrons transferred into the quantum dot light-emitting layer 126 may be adjusted, and the transport balance of electrons and holes in the second light-emitting device 114 may be improved. As a result, the luminous efficiency of the second light-emitting device 114 is improved.

In some examples, the molar percentage of Mg is greater than 0 and less than or equal to 40%. In some other examples, the molar percentage of Mg is greater than 0 and less than or equal to 30%. In yet some other examples, the molar percentage of Mg is greater than 0 and less than or equal to 20%.

For example, the molar percentage of Mg in the fourth electron transporting layer 134 may be 10%, 20%, 30%, 40%, or the like.

It will be understood that in a case where, in the fourth electron transporting layer 134, the molar percentage of Mg is greater than 0 and less than or equal to 50%, and the molar percentage of Zn is greater than or equal to 50% and less than 100%.

In some embodiments, the molar percentage of Mg in the fourth electron transporting layer 134 is in a range of 1% to 20%, inclusive.

In some examples, the molar percentage of Mg in the fourth electron transporting layer 134 may be in a range of 2% to 20%, inclusive, a range of 5% to 15%, inclusive, a range of 7% to 12%, inclusive, or the like. For example, in the fourth electron transporting layer 134, the molar percentage of Mg may be 5%, 8%, 10%, 15%, or the like.

It will be understood that, by adjusting the molar percentage of Mg in the fourth electron transporting layer 134, the electron mobility of the fourth electron transporting layer 134 and the energy (for example, the energy of the valence band maximum VBM and the energy of the conduction band minimum CBM) of the fourth electron transporting layer 134 may be adjusted, so that the number of electrons transferred into the quantum dot light-emitting layer 126 may be adjusted, and the transport balance of electrons and holes in the second light-emitting device 114 may be improved. As a result, the luminous efficiency of the second light-emitting device 114 is improved.

It will be understood that, in a case where, in the fourth electron transporting layer 134, the molar percentage of Mg is in a range of 1% to 20%, inclusive, the molar percentage of Zn is in a range of 80% to 99%, inclusive.

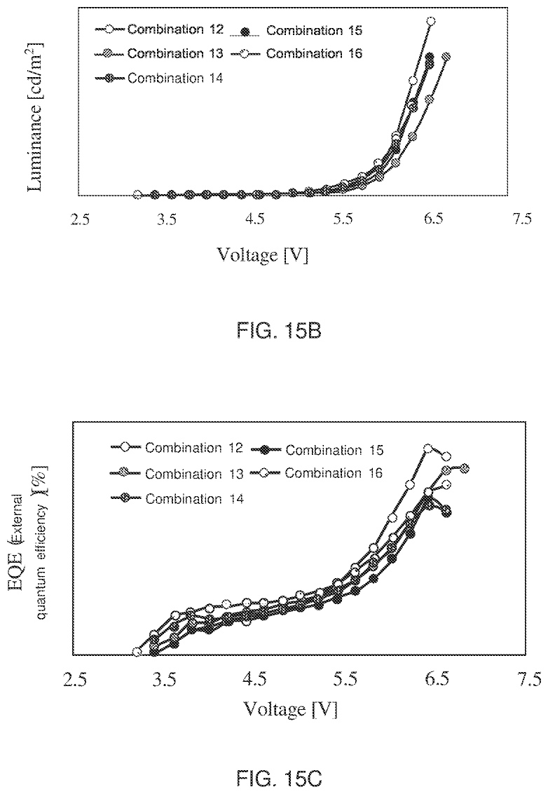

FIG. 15A is curve graph showing a variation of a current density with a voltage, in accordance with yet some other embodiments. FIG. 15B is a curve graph showing a variation of a luminance with a voltage, in accordance with some embodiments. FIG. 15C is a curve graph showing a variation of an external quantum efficiency with a voltage, in accordance with yet some other embodiments.

Hereinafter, referring to FIGS. 15A to 15C, in some embodiments of the present disclosure, the current density, the luminance, and the external quantum efficiency of the second light-emitting device 11 will be illustrated in a case where the molar percentage of Mg in the fourth electron transporting layer 134 in the second light-emitting device 114 is different.

It will be understood that, in FIG. 15A, the abscissa represents voltage in V, and the ordinate represents current density in mA/cm²; in FIG. 15B, the abscissa is voltage in V, and the ordinate is luminance in candela per square meter (cd/m²); in FIG. 15C, the abscissa represents voltage in V, and the ordinate represents the external quantum efficiency (EQE). It will be understood that, EQE is equal to the number of the emitted photons divide by the number of the injected holes. The greater the EQE, the better the light emission performance of the light-emitting device 110.

As shown in FIGS. 15A to 15C, Combinations 12 to 16 are combinations of different electron transporting layers 130 in a case where the molar percentage of Mg in the fourth electron transporting layer 132 is different.

In Combination 12, the third electron transporting layer 133 is a ZnO film with a thickness of 10.5 nm; the fourth electron transporting layer 134 is a ZnMgO film with a thickness of 9 nm; and the fifth electron transporting layer 135 is a ZnO film with a thickness of 10.5 nm. In the fourth electron transporting layer 134, the molar percentage of Mg in ZnMgO is 8%.

In Combination 13, the third electron transporting layer 133 is a ZnO film with a thickness of 10.5 nm; the fourth electron transporting layer 134 is a ZnMgO film with a thickness of 9 nm; and the fifth electron transporting layer 135 is a ZnO film with a thickness of 10.5 nm. In the fourth electron transporting layer 134, the molar percentage of Mg in ZnMgO is 6.5%.

In Combination 14, the third electron transporting layer 133 is a ZnO film with a thickness of 10.5 nm; the fourth electron transporting layer 134 is a ZnMgO film with a thickness of 9 nm; and the fifth electron transporting layer 135 is a ZnO film with a thickness of 10.5 nm. In the fourth electron transporting layer 134, the mole percentage of Mg in ZnMgO is 5%.

In Combination 15, the third electron transporting layer 133 is a ZnO film with a thickness of 10.5 nm; the fourth electron transporting layer 134 is a ZnMgO film with a thickness of 9 nm; and the fifth electron transporting layer 135 is a ZnO film with a thickness of 10.5 nm. In the fourth electron transporting layer 134, the molar percentage of Mg in ZnMgO is 2.5%.

In Combination 16, the third electron transporting layer 133, the fourth electron transporting layer 134, and the fifth electron transporting layer 135 are all made of ZnO. That is, in this case, the at least two electron transporting layers 130 can be regarded as one electron transporting layer 130, which has a thickness of 30 nm.

As shown in FIGS. 15A to 15C, as for the second light-emitting device 114 including three electron transporting layers 130 (such as Combination 13, Combination 14, or Combination 15, which includes the third electron transporting layer 133, the fourth electron transporting layer 134, and the fifth electron transporting layer 135), the current density, the luminance, and the EQE are all better than those of the single electron transporting layer 130 (Combination 16). That is, in a case where three electron transporting layers 130 are included, the second light-emitting device 114 may have a good light emission performance.

It will be understood that, in a case where three electron transporting layers 130 (Combination 12, Combination 13, Combination 14, or Combination 15) are included, the fourth electron transporting layer 134 is made of ZnMgO, it is possible to reduce electron mobility by doping with Mg ions, so that the number of electrons in the quantum dot light-emitting layer 126 is reduced, and the luminous efficiency of the second light-emitting device 114 is improved.

In addition, in a case where the third electron transporting layer 133 is made of ZnO, the fourth electron transporting layer 134 is made of ZnMgO, and the fifth electron transporting layer 135 is made of ZnO, an energy difference may be generated between the third electron transporting layer 133 made of ZnO, the fourth electron transporting layer 134 made of ZnMgO, and the fifth electron transporting layer 135 made of ZnO, so as to form an electron transport barrier, so that it is possible to block the transmission of electrons to the quantum dot light-emitting layer 126, and balance the transmission capabilities of electrons and the holes in the second light-emitting device 114.

As shown in FIGS. 15A and 15B, in a case where the voltage is increased, the second light-emitting device 114 in which Combination 12 is included has the highest EQE and the highest current efficiency, thereby improving the light emission performance of the second light-emitting device 114.

However, as for the second light-emitting device 114 in which Combination 13, Combination 14, or Combination 15 is included, in a case where the voltage is increased, the current density and the luminance are all increased, which affects the EQE and the current efficiency of the second light-emitting device 114.

Thus, in some embodiments, in a case where the second light-emitting device 114 includes the third electron transporting layer 133, the fourth electron transporting layer 134, and the fifth electron transporting layer 135, the molar percentage of Mg in the fourth electron transporting layer 134 is approximately 8%.

It can be seen form the above, with this configuration, the current efficiency and the external quantum efficiency of the second light-emitting device 114 may be improved, so that the light emission performance of the second light-emitting device 114 may be improved.

In some examples, in a case where the third electron transporting layer 133 is a ZnO film with a thickness of 10.5 nm, and the fourth electron transporting layer 134 is a ZnMgO film with a thickness of 9 nm, in which the molar percentage of Mg in ZnMgO is 8%, and the fifth electron transporting layer 135 is a ZnO film with a thickness of 10.5 nm, the energy level relationship between the third electron transporting layer 133, the fourth electron transporting layer 134, and the fifth electron transporting layer 135 is as shown in FIG. 12A.

In some examples, values of the energy of the conduction band minimum CBM and the energy of the valence band maximum VBM of the ZnO film, the ZnMgO film (in which the molar percentage of Mg is 5%) and the ZnMgO film (in which the molar percentage of Mg is 8%) are shown in Table 1.

TABLE 1

| | VBM (eV) | CBM (eV) |
|---|---|---|
| ZnO | −7.3 | −4.1 |
| ZnMg(5%)O | −7.4 | −4.0 |
| ZnMg(8%)O | −7.4 | −3.6 |

It will be understood that, by setting the electron transporting layers 130 to be as different n-type oxide films and adjusting the molar percentage of elements in the n-type oxide films, the energy of the electron transporting layers 130 can be adjusted, so that an electron barrier is formed between the at least two electron transporting layers 130. Thus, it is possible to block the transmission of electrons to the quantum dot light-emitting layer 126, and increase the consistency of the electron mobility and the hole mobility, thereby improving the luminous efficiency of the light-emitting device 110.

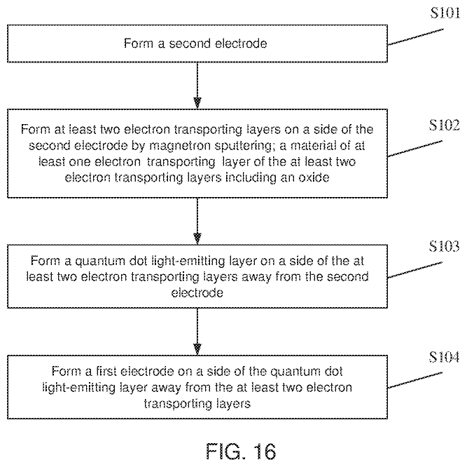

FIG. 16 is a flow diagram of a method of manufacturing a light-emitting device, in accordance with some embodiments.

In another aspect, some embodiments of the present disclosure provide a method of manufacturing a display panel. It will be understood that the method of manufacturing the display panel provided by the embodiments of the present disclosure is used for manufacturing the display panel 100 as described above. Therefore, all the beneficial effects described above are achieved, and are not repeated here.

In some embodiments, the method of manufacturing the display panel includes forming a plurality of light-emitting devices. As shown in FIG. 16, a step of forming a light-emitting device includes following steps.

In the step S101, a second electrode is formed.

In the step S102, at least two electron transmission layers are formed on a side of the second electrode by magnetron sputtering. A material of at least one electron transporting layer of the at least two electron transporting layers includes an oxide.

It will be understood that, the at least two electron transporting layers 130 are formed by magnetron sputtering. In this way, the surface state of the oxide (e.g., ZnO) in the electron transporting layer(s) 130 may be reduced, so as to reduce the interaction between the oxide in the electron transporting layer 130 and the quantum dot light-emitting layer 126, which is beneficial to reducing the non-radiative recombination (e.g., auger recombination) loss caused by the interface defect, and improving the luminous efficiency of the light-emitting device 110.

Furthermore, the influence of the electron transporting layer 130 formed later on the electron transporting layer 130 formed earlier may be reduced, and the electron transporting layer 130 formed earlier is not easily damaged, so that the thickness and the material of the at least two electron transporting layers 130 can be flexibly controlled. As a result, the optical properties and the electrical properties of the light-emitting device 110 can be flexibly controlled, the consistency of the electron mobility and the hole mobility in the first light-emitting device 112 can be improved, the transmission capabilities of electrons and holes in the first light-emitting device 112 can be balanced, and the consistency of the number of electrons and the number of holes in the quantum dot light-emitting layer 126 can be improved, so that the luminous efficiency of the first light-emitting device 112 can be improved.

In addition, in the ZnO film formed by magnetron sputtering will have no or only a small amount of ZnO in the form of nanoparticles, so that the surface roughness of the ZnO film can be reduced.

Moreover, the at least two electron transporting layers 130 formed by magnetron sputtering may be suitable for the high-resolution display, and the process is simple, which can be adapted to the manufacturing process of the driving backplate 150, thereby improving the display performance of the display panel 100, and reducing the production cost of the display panel 100.

Besides, the material of at least one electron transporting layer of the at least two electron transporting layers 130 includes oxide, so that the electrons can be migrated into the quantum dot light-emitting layer 126 through the electron transporting layer(s).

In some examples, the material of any electron transporting layer 130 includes any one of ZnO, GZO, AZO, IZO, IGZO, and ZnMgO, and the materials of any adjacent two electron transporting layers 130 are different.

It will be understood that after the at least two electron transporting layers 130 are formed, the longitudinal depth and distribution intensity of each element in different electron transporting layers 130 can be measured by using the time of flight secondary ion mass spectrometer (TOF-SIMS), so as to obtain the material and thickness of each electron transporting layer 130.

In the step S103, a quantum dot light-emitting layer is formed on a side of the at least two electron transporting layers away from the second electrode.

In some examples, after forming the at least two electron transporting layers 130, a coating process, with a quantum dot solution, is performed on the side of the second electron transporting layer 132 away from the second electrode 124 by means of spin coating with a quantum dot solution, knife coating with a quantum dot solution, or ink-jet printing with a quantum dot solution. Then, a baking process is performed in a heating platform or an oven at the temperature of 80° C. to 150° C. for 5 minutes to 30 minutes. For example, it is possible to control the temperature of the heating platform to be 120° C., and the baking time may be 10 minutes, so as to form the quantum dot light-emitting layer 126 on the side of the at least two electron transporting layers 130 away from the second electrode 124.

In the step S104, a first electrode is formed on a side of the quantum dot light-emitting layer away from the at least two electron transporting layers.

In some examples, the first electrode 122 may be formed on the side of the quantum dot light-emitting layer 126 away from the at least two electron transporting layers 130 by evaporation.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel comprising a plurality of light-emitting devices, wherein any of the light-emitting devices includes:
a first electrode and a second electrode;
a quantum dot light-emitting layer located between the first electrode and the second electrode; and
at least two electron transporting layers, wherein the at least two electron transporting layers are stacked and located between the second electrode and the quantum dot light-emitting layer;
wherein the plurality of light-emitting devices includes a first light-emitting device and a second light-emitting device, the first light-emitting device is used to emit light of a first color, the second light-emitting device is used to emit light of a second color, and a wavelength of the light of the first color is greater than a wavelength of the light of the second color; and
a number of electron transporting layers in the first light-emitting device is less than a number of electron transporting layers in the second light-emitting device.

2. The display panel according to claim 1, wherein a sum of thicknesses of at least two electron transporting layers in the first light-emitting device is greater than a sum of thicknesses of at least two electron transporting layers in the second light-emitting device.

3. The display panel according to claim 2, further comprising a driving backplate, the plurality of light-emitting devices being located on a side of the driving backplate; the second electrode being close to the driving backplate relative to the first electrode; wherein
the first light-emitting device includes a first first electrode, and the second light-emitting device includes a second first electrode; a distance between a surface of the first first electrode away from the driving backplate and the driving backplate is greater than a distance between a surface of the second first electrode away from the driving backplate and the driving backplate.

4. The display panel according to claim 1, wherein at least two electron transporting layers in the first light-emitting device include:
a first electron transporting layer and a second electron transporting layer, an electron mobility of the second electron transporting layer is less than an electron mobility of the first electron transporting layer.

5. The display panel according to claim 4, wherein the first electron transporting layer is close to the second electrode relative to the second electron transporting layer, and an energy of a conduction band minimum of the first electron transmission layer is less than an energy of a conduction band minimum of the second electron transmission layer.

6. The display panel according to claim 4, wherein a material of the first electron transporting layer includes any one of zinc oxide (ZnO), gallium zinc oxide (GZO), aluminum zinc oxide (AZO), indium zinc oxide (IZO), indium gallium zinc oxide (IGZO), and magnesium zinc oxide (ZnMgO), a material of the second electron transporting layer includes any one of ZnO, GZO, AZO, IZO, IGZO, and ZnMgO, and the material of the first electron transporting layer is different from the material of the second electron transporting layer.

7. The display panel according to claim 6, wherein the material of the second electron transporting layer includes ZnMgO; in the second electron transporting layer, a molar percentage of magnesium (Mg) is greater than 0 and less than or equal to 50%, and a sum of the molar percentage of Mg and a molar percentage of zinc (Zn) is 1.

8. The display panel according to claim 7, wherein in the second electron transporting layer, the molar percentage of Mg is in a range of 1% to 20%, inclusive.

9. (canceled)

10. The display panel according to claim 4, wherein a thickness of the first electron transporting layer is greater than 0 nm and less than or equal to 60 nm; and/or
a thickness of the second electron transporting layer is greater than 0 nm and less than or equal to 60 nm; and
the thickness of the first electron transporting layer is greater than the thickness of the second electron transporting layer.

11-12. (canceled)

13. The display panel according to claim 1, wherein the plurality of light-emitting devices further include a third light-emitting device; third light-emitting device is used to emit light of a third color, and the wavelength of the light of the second color is greater than a wavelength of the light of the third color;
the number of the electron transporting layers in the first light-emitting device is less than a number of electron transporting layers in the third light-emitting device.

14. The display panel according to claim 13, wherein at least two electron transporting layers of at least one light-emitting device of the second light-emitting device and the third light-emitting device include:
a third electron transporting layer, a fourth electron transporting layer, and a fifth electron transporting layer; an electron mobility of the fourth electron transporting layer is smaller than an electron mobility of the third electron transporting layer; and the electron mobility of the fourth electron transporting layer is smaller than an electron mobility of the fifth electron transporting layer.

15. The display panel according to claim 14, wherein the third electron transporting layer, the fourth electron transporting layer, and the fifth electron transporting layer are sequentially far away from the second electrode in a direction from the second electrode to the quantum dot light-emitting layer;
wherein an energy of a conduction band minimum of the third electron transporting layer is less than an energy of a conduction band minimum of the fourth electron transporting layer; or the energy of the conduction band minimum of the fourth electron transporting layer is less than an energy of a conduction band minimum of the fifth electron transporting layer.

16. The display panel according to claim 15, wherein the energy of the conduction band minimum of the third electron transporting layer is equal to the energy of the conduction band minimum of the fifth electron transporting layer.

17. The display panel according to claim 14, wherein a material of the third electron transporting layer includes any one of ZnO, GZO, AZO, IZO, IGZO, and ZnMgO, a material of the fourth electron transporting layer includes any one of ZnO, GZO, AZO, IZO, IGZO, and ZnMgO, and a material of the fifth electron transporting layer includes any one of ZnO, GZO, AZO, IZO, IGZO, and ZnMgO; the material of the fourth electron transporting layer is different from the material of the third electron transporting layer; and/or
the material of the fourth electron transporting layer is different from the material of the fifth electron transporting layer.

18. The display panel according to claim 17, wherein the material of the fourth electron transporting layer includes ZnMgO; and in the fourth electron transporting layer, a molar percentage of Mg is greater than 0 and less than or equal to 50%, and a sum of the molar percentage of Mg and a molar percentage of Zn is 1.

19-20. (canceled)

21. The display panel according to claim 14, wherein the second light-emitting device includes a third electron transporting layer, a fourth electron transporting layer, and a fifth electron transporting layer, a thickness of the third electron transporting layer is greater than 0 nm and less than or equal to 40 nm, a thickness of the fourth electron transporting layer is greater than 0 nm and less than or equal to 30 nm, and a thickness of the fifth electron transporting layer is greater than 0 nm and less than or equal to 40 nm; and
the third light-emitting device includes a third electron transporting layer, a fourth electron transporting layer, and a fifth electron transporting layer, a thickness of the third electron transporting layer is greater than 0 nm and less than or equal to 30 nm, a thickness of the fourth electron transmission layer is greater than 0 nm and less than or equal to 20 nm, and a thickness of the fifth electron transporting layer is greater than 0 nm and less than or equal to 30 nm.

22-24. (canceled)

25. The display panel according to claim 1, wherein a sum of thicknesses of the at least two electron transporting layers is in a range of 5 nm to 150 nm, inclusive.

26-27. (canceled)

28. The display panel according to claim 1, any of the light-emitting devices further includes:
an electron injection layer located between the second electrode and the at least two electron transporting layers;
a hole injection layer located between the first electrode and the quantum dot light-emitting layer;
a hole transporting layer located between the hole injection layer and the quantum dot light-emitting layer; and
a light coupling layer located on a side of the first electrode away from the hole injection layer.

29. A method of manufacturing a display panel, comprising forming a plurality of light-emitting devices; wherein forming a light-emitting device includes:
forming a second electrode;
forming at least two electron transporting layers on a side of the second electrode by magnetron sputtering; wherein a material of at least one electron transporting layer of the at least two electron transporting layers includes an oxide;
forming a quantum dot light-emitting layer on a side of the at least two electron transporting layers away from the second electrode; and
forming a first electrode on a side of the quantum dot light-emitting layer away from the at least two electron transporting layers.

30. A display apparatus, comprising the display panel according to claim 1.
